(19) United States
(12) Patent Application Publication
(10) Pub. No.: US 2024/0409747 A1
(43) Pub. Date: Dec. 12, 2024

(54) COMPOSITION COMPRISING CARBON BLACK AND EXPANDED GRAPHITE AND SHAPED ARTICLES AND SUBSTRATE COATINGS COMPRISING SAME, USES THEREOF AND METHODS FOR REDUCING VOLUME RESISTIVITY AND FOR PROVIDING ELECTROMAGNETIC INTERFERENCE SHIELDING AS WELL AS THERMAL CONDUCTIVITY

(71) Applicant: IMERTECH SAS, Paris (FR)

(72) Inventors: Jerome CREPIN-LEBLOND, Colomiers (FR); Anna ELLETT, Geraardsbergen (BE)

(21) Appl. No.: 18/699,962

(22) PCT Filed: Oct. 27, 2022
(86) PCT No.: PCT/EP2022/080085

§ 371 Date: Apr. 10, 2024

(30) Foreign Application Priority Data
Nov. 5, 2021 (EP) 21306557.6

(51) Int. Cl. C09C 1/00; C08K 3/04; C08K 7/24; H05K 9/00

(52) U.S. Cl. CPC C09C 1/0081; C08K 3/04; C08K 7/24; H05K 9/0081; C01P 2004/61; C01P 2004/64; C01P 2006/11; C01P 2006/19; C01P 2006/32; C01P 2006/40; C08K 2201/001; C08K 2201/005; C08K 2201/006; C08K 2201/011

(57) ABSTRACT

The present invention is directed to compositions comprising carbon black and expanded graphite as well as shaped articles and coatings for substrates comprising the compositions. The present invention also relates to the use thereof and methods for reducing electrical resistivity and providing electromagnetic interference shielding as well as thermal conductivity. The compositions of the invention allow for high electrical conductivity, EMI shielding performance as well as thermal conductivity without compromising rheological properties like fluidity or viscosity, for example measured as the melt flow rate, or mechanical properties such as, impact resistance, tensile strength or elongation at break.

### FIELD OF THE INVENTION

The present invention is directed to compositions comprising carbon black and expanded graphite as well as shaped articles and substrate coatings comprising the compositions. The present invention also relates to the use thereof and methods for reducing electrical resistivity and providing electromagnetic interference shielding as well as thermal conductivity.

### STATE OF THE ART

In the art, it is well-known to fine-tune physical and chemical properties of polymer compositions and products comprising or made from said polymer compositions by using fillers or additives. For example, fillers based on carbon, silicon and metal have been used to reduce electrical resistivity and to provide electromagnetic interference shielding as well as thermal conductivity.

Electrical resistivity, ρ, sometimes also referred to as electrical resistivity or specific electrical resistance, is a material property related to the degree of the material's resistance to electric current expressed in the SI units Ohm·m or Ohm·cm (Ω·m or Ω·cm, respectively). Volume resistivity is usually determined according to ASTM D-991, ASTM D-4496, ISO 3915, or ISO 1853 standard test methods. A low-resistivity material is a material which readily conducts electric current.

Thermal conductivity is a material property quantifying a material's ability to conduct heat expressed in the SI units W·m⁻¹·K⁻¹ or W·cm⁻¹·K⁻¹. A material having high thermal conductivity is very efficient at conducting heat. A material's thermal conductivity is commonly determined by standard tests according to ASTM E 1461 or ISO 22007.

Electromagnetic interference (EMI) is a physical phenomenon that occurs when an external source affects an electrical circuit by electromagnetic induction, electrostatic coupling or conduction. EMI perturbs or even completely degrades the performance of an electric circuit.

EMI is a major problem, where a multitude of electronic devices is used, for example in medical, military, aerospace, or automotive applications. As an example, due to the increased use of electronic equipment on one side and electromagnetic waves for wireless communication on the other side, the risk of undesired crosstalk is rising.

In order to reduce or even completely eliminate the negative impact of EMI on electric circuits, electromagnetic shielding, also referred to as EMI shielding, is used. Electromagnetic shielding is typically achieved by electrically conductive or magnetic enclosures put around electric devices to isolate same from their environment. A common approach for EMI shielding is to use housings made from plastic which is equipped with conductive additives or metal-based shielding materials, e.g. metal coatings. Also, composite materials are known for EMI shielding applications.

A material's EMI shielding performance or EMI shielding efficiency (EMI SE) is commonly expressed as the attenuation in decibel (dB) of an electromagnetic wave at a certain frequency. EMI SE can for example be determined by standard tests according to ASTM D-4935 or IEE 299 or methods derived therefrom.

A material's EMI shielding performance depends on several factors, including the material's electrical resistivity or its inverse, the electrical conductivity. In the art, electrical conductivity and EMI shielding of composite materials is achieved by reducing the composite material's electrical resistivity, for example, by adding conductive additives or fillers. Typical conductive additives or fillers known in the art are metal-based, silicon-based or carbon-based, e.g. metal powder, metal flakes, or metal fibers, glass fibers, silicon fibers, natural graphite, synthetic graphite, surface modified graphite, graphite nanoplatelets, multiwall carbon nanotubes, single wall carbon nanotube, carbon nanostructures, or metal-coated graphite. A conductive additive's characteristics such as form, particle size, morphology and aspect ratio affect the material's conductivity.

In this context, it is also known to use carbon black or expanded graphite as carbon-based conductive fillers.

The structure of carbon black consists of primary particles made of concentrically arranged continuous layers of hexagonally arranged carbon atoms containing small graphitic or turbostratic domains. The nearly spherically shaped primary particles with average diameter of few tens of nanometers are coalesced by continuous carbon layers forming covalent bonded rigid aggregates. These aggregates show a three-dimensionally branched structure of chain-, fiber- or grape-like arranged primary particles with sizes of up to several hundred of nanometers. A characteristic feature of conductive carbon black is the large size of the aggregate structure.

Carbon black is widely used as an additive in polymers or compounding compositions to provide electrical conductivity and also EMI shielding. As an example, CN105885226A relates to network cable insulating materials comprising carbon black providing for electromagnetic interference shielding.

Graphite is the most common allotrope of carbon and is characterized by good electrical, thermal, and lubricating properties. Graphite powders are suitable fillers to improve the conductivity and tribological properties of polymer composites. The term “graphitic carbon” includes various types of carbon powders with different levels of crystallinity like natural and synthetic graphite. Natural graphite from ore deposits occurs in three main forms: flake graphite, lump or vein graphite, and amorphous graphite. Synthetic graphite is manufactured from natural or petroleum carbon precursors in high temperature processes that transform amorphous carbon to carbon of higher structural order.

Expanded graphite is an exfoliated form of graphite (Herold et al. 1994; Herold A, Petitjean D, Furdin G, Klatt M (1994) Exfoliation of graphite intercalation compounds: classification and discussion of the processes from new experimental data relative to graphite acid compounds. Mater Sci Forum 152-153:281-287 (Soft chemistry routes to new materials). The production process is based on the thermal exfoliation of graphite intercalation compounds formed by the treatment of graphite flakes with strong acid in the presence of an oxidizing agent. The most prominent graphite intercalation compound used in industrial processes is graphite sulfate, Cm+HSO4n H2SO4, prepared by reacting graphite flakes with concentrated sulfuric acid and hydrogen peroxide, ammonium peroxydisulfate, and nitric or chromic acid as the oxidizing agent. Under these chemical conditions, graphite is oxidized and at the same time sulfate anions and sulfuric acid molecules are inserted between the graphite layers. Not every graphite interlayer is necessarily occupied by guest species, but intercalation compounds of different stages exist. The stage that can be achieved depends on the chemical conditions, but usually the actual composition may vary and causes the typical non-stoichiometry of these graphite salts. Other reagents that can be used are nitric acid, chloric acid, and nitric acid in acetic acid. The resulting graphite salt is isolated by filtration, washing, and drying. The expansion of the graphite salts occurs at temperatures above 300° C. At industrial scale, this process is conducted by thermal shock, in which the material is exposed briefly to temperatures above 700° C. which cause the decomposition of the guest anions and acid molecules between the graphite layers to gaseous products that exfoliate the graphite layers. As an alternative, microwave radiations can be used for the exfoliation process. After expansion, the powder is composed by coarse “wormlike”-shaped grains. Usually, expanded graphite cannot be used in this form due to the extremely low bulk density, and it is ground to fine particle size or compressed to graphite foils or graphite “paper.” The graphite particles resulting from grinding of expanded graphite are very anisometric (high aspect ratio) and extremely effective as conductive additive at low loadings. Specially granulated expanded graphite materials have shown advantages in the incorporation into polymers using industrial feeding and mixing equipment (international patent application published as WO 2012/020099 A1). The largest industrial applications of exfoliated graphite are seals and gaskets from polymer-impregnated graphite foils.

Expanded graphite is known to provide electrical conductivity, thermal conductivity and to have a positive impact on lubrification performance. Advantageously, expanded graphite may be used in smaller loading amounts compared with standard graphite and can still achieve the same benefit. Expanded graphite has been known for years and also its use in polymer composites, see, for example, U.S. Pat. Nos. 1,137,373 and 1,191,383 as well as U.S. Pat. Nos. 4,946,892, and 5,582,781.

U.S. Pat. No. 4,530,949 relates to housing for electrical or electronic equipment prepared from an organic thermosetting resin moulding composition comprising expanded graphite in combination with glass fibers. The molded article provides for a resistivity of not greater than 0.5 Ohm·cm and a measured attenuation of 32-64 dB at frequencies of 50 to 1000 MHz. However, disadvantageously the compositions according to Examples 1 to 3 of U.S. Pat. No. 4,530,949 contain expanded graphite in combination with glass fibers, which do not allow for light-weight applications. Also, it is known in the art that thermoset resins generally allow for lower percolation thresholds of conductive fillers like carbon black and expanded graphite compared to thermoplastics. In other words, in thermoset resins, electrical conductivity can be achieved at lower conductive filler loadings compared to thermoplastics. Also, thermosets comprising mixtures of carbon black and expanded graphite are generally known to be difficult to be processed at high filler loadings.

U.S. Pat. No. 4,704,231 describes composites comprising low-density exfoliated graphite flakes in a polymer matrix providing for a electrical resistivity of the composite of 0.5 Ohm·cm or below. However, disadvantageously, low-density exfoliated graphite flakes cannot be used in thermoplastics at high loadings because this results in poor processability.

US 2006/0148965 A1 is directed to expanded graphite inter alia for use in polymer composites. However, the composites of US 2006/0148965 A1 disadvantageously provide for resistivities of greater than 10 Ohm·cm only and not below. Also, composites comprising up to 30 wt.-% carbon black are reported to provide for resistivities of not below 100 Ohm·cm. Thus, the composites of US 2006/0148965 A1 do not allow for efficient conductivity and thus do not allow for efficient EMI shielding.

Also, blends of carbon-based additives such as carbon nanotubes and carbon-black or graphene or graphene-like or graphite in polymeric matrices are known to provide for improved conductivity and also sometimes better mechanics. However, the disadvantage of using conductive fillers like carbon nanotubes and carbon-black or graphene or graphene-like or graphite is that usually high loadings are required to provide for good electrical and/or thermal conductivity. High loadings of conductive fillers like carbon nanotubes and carbon-black or graphene or graphene-like or graphite, however, result in poor processability, e.g. due to high viscosities.

Moreover, the use of carbon black in combination with expanded graphite in compounding compositions is known in the art. For example, KR 2018/0022398 A relates to a heating pad with a heat-dissipating polymer composite material comprising thermally conductive carbonaceous material such as carbon nanotube (CNT), graphene nanoplate (GNP), expanded graphite (EG) uniformly dispersed in the polymer. The heating pad is also described to provide for electromagnetic interference shielding, which, however, is not quantified. Moreover, carbon nanotubes disadvantageously often provide for low dispersion in a polymer and, as a consequence, result in high percolation thresholds. Also, usually one seeks to avoid carbon nanotubes as they are known to pose health hazards. Furthermore, the composite material according to KR 2018/0022398 suffers from the fact that a combination of three conductive additives is needed, which is neither resource nor cost efficient.

As another example, U.S. Pat. No. 11,024,849 B2 describes fast-chargeable lithium-ion and lithium metal batteries comprising polymer foams containing electrically conductive carbonaceous material like inter alia expanded graphite, carbon black or combinations thereof. However, U.S. Pat. No. 11,024,849 B2 does not provide any intelligence about electromagnetic interference shielding or thermal conductivity.

The article by Leso et al., Journal of Polymers and the Environment, 2020, 28, pp. 2021-2100, https://doi.org/10.1007/s10924-020-01753-4 addresses electromagnetic interference shielding effectiveness of conductive polyvinylidene fluoride (rPVDF) composites with carbon black, expanded graphite and mixtures thereof. In particular, Leso et al. describe that composites containing 5 wt % of a combination of carbon black and expanded graphite in a ratio of 1.5 (3 wt.-% carbon black:2 wt.-% expanded graphite) result in an attenuation of electromagnetic waves at a frequency of 12.3 GHz of around 97% corresponding to around −15 dB. The rPVDF composites are also described to provide for acceptable processability. However, disadvantageously, the composites according to Leso et al. do not provide for attenuation of more than −15 dB which, however, is required for improved electromagnetic interference shielding.

### OBJECT OF THE INVENTION

Improving a composite material's electric conductivity and EMI shielding performance as well as thermal conductivity could in principle be achieved by increasing the content of conductive additives (conductive fillers). However, this approach is limited as high filler loadings negatively affect the composite material's rheological and mechanical properties such as viscosity, tensile strength or elongation at break. Thus, at too high filler loadings, a composition's processability decreases. For example, at high filler loadings of e.g. more than 50 wt.-% based on the total weight of the composition, extrusion becomes difficult, and injection molding oftentimes becomes even impossible. Also, too high filler loadings are disadvantageous as the weight of the resulting compositions or articles made therefrom increases.

It is an object of the present invention to solve the shortcomings of the prior art described hereinabove. Against this background, the present invention aims to optimize conductivity, EMI shielding efficiency and thermal conductivity on the one hand and the amount of conductive additives used, i.e. conductive filler loadings, on the other. In particular, it is desired to reduce conductive filler loadings in composites and to maintain or even improve conductivity, EMI shielding efficiency and thermal conductivity of the composites. Moreover, it is desirable to have available compositions allowing for high electrical conductivity, EMI shielding performance as well as thermal conductivity without compromising rheological properties like fluidity or viscosity, for example measured as the melt flow rate, or mechanical properties such as, impact resistance, tensile strength or elongation at break. Also, it is desirable to have available compositions allowing for light-weight materials having high electrical conductivity, EMI shielding performance as well as thermal conductivity.

### SUMMARY OF THE INVENTION

To achieve one or more or all of these objects, the present invention provides a composition comprising carbon black and expanded graphite according to claim 1, or claim 6, or claim 11.

Further, the present invention also provides for a shaped article according to claim 17 or a coated substrate according to claim 18 comprising the claimed composition.

Moreover, the present invention is directed to use of the claimed composition or the shaped article or the substrate coating of the present invention for providing EMI shielding, volume resistivity and/or thermal conductivity, see claims 19 to 24.

Advantageous embodiments of the composition, the shaped article, the coated substrate, the use and the method of the present invention are the subject of the respective dependent claims.

### BRIEF DESCRIPTION OF THE FIGURES

FIG. 1 shows the results of melt flow rate measurements at 230° C. and 5 kg for polypropylene composites with different combinations and ratios of carbon black and expanded graphite fillers.

FIG. 2A shows the results of melt flow rate measurements at 240° C. and 5 kg for polyamide composites with different loadings of carbon black (Ensaco® 250 G) and expanded graphite (Timrex® C-THERM™ 011) and synthetic graphite (Timrex® KS44).

FIG. 2B shows the results of melt flow rate measurements for polyamide composites at 240° C. and 12.5 kg with different loadings of carbon black (Ensaco® 250 G) and expanded graphite (Timrex® C-THERM™ 011) and a combination thereof.

FIG. 3 shows a plot of volume resistivity (in Ohm·cm) measured for polypropylene samples prepared from compositions with conductive fillers comprising blends of carbon black (Ensaco® 250 G) and expanded graphite (Timrex® C-THERM™ 011) or synthetic graphite (Timrex® SFG44) at total filler amounts of 30 wt.-% based on the total weight of the composition versus the fraction of expanded graphite or synthetic graphite in the conductive additive filler blend.

FIG. 4 shows a plot of volume resistivity (in Ohm·cm) measured for polyamide samples with different conductive fillers versus the total additive content in wt.-% based on the total weight of the composition.

FIG. 5A shows corrected dependent EMI shielding efficiencies of polypropylene composites with the following compositions in order of decreasing shielding efficiency: (i) sample PP-5.3 with 15 wt.-% carbon black (Ensaco® 250 G)/15 wt.-% expanded graphite (Timrex® C-THERM™ 011), (ii) sample PP-5.10 with 10 wt.-% carbon black (Ensaco® 250 G)/10 wt.-% expanded graphite (Timrex® C-THERM™ 011)/10 wt.-% carbon fiber (Tenax A HT P802 3 mm), (iii) sample PP-5.9 with 15 wt.-% carbon black (Ensaco® 250 G)/15 wt.-% carbon fiber (Tenax A HT P802 3 mm), (iv) sample PP-5.6 with 15 wt.-% carbon black (Ensaco® 250 G)/15 wt.-% expanded graphite (Timrex® C-THERM™ 301), (v) sample PP-5.7 with 15 wt.-% carbon black (Ensaco® 250 G)/15 wt.-% expanded graphite (Timrex® C-THERM™ MAX HD), (vi) sample PP-5.8 with 7.5 wt.-% carbon black (Ensaco® 350 G)/15 wt.-% expanded graphite (Timrex® C-THERM™ 011), and (vii) neat polypropylene without conductive additive.

FIG. 5B shows corrected vs non-corrected EMI shielding efficiencies for selected polypropylene compositions comprising (i) sample PP-5.3 with 15 wt.-% carbon black (Ensaco® 250 G)/15 wt.-% expanded graphite (Timrex® C-THERM™ 011), (ii) sample PP-5.1 with 30 wt.-% carbon black (Ensaco® 250 G), (iii) sample PP-5.5 with 30 wt.-% expanded graphite (Timrex® C-THERM™ 011) and (iv) control sample with neat polypropylene without conductive additive in the order of decreasing EMI shielding efficiency.

FIG. 6A shows thermal conductivities of polypropylene composites with blends of carbon black (Ensaco® 250 G) and expanded graphite (Timrex® C-THERM™ 011) in varying amounts.

FIG. 6B shows thermal conductivities of polyamide composites with different amounts of various fillers.

FIG. 7A shows tensile moduli for polypropylene composites with blends of carbon black (Ensaco® 250 G) and expanded graphite (Timrex® C-THERM™ 011) or carbon black (Ensaco® 250 G) and synthetic graphite (Timrex® SFG44) in varying amounts.

FIG. 7B shows tensile moduli for polyamide composites with different amounts of various fillers.

### DETAILED DESCRIPTION OF THE INVENTION

### Definitions

In context of the present invention, the term “electrical resistivity” sometimes also referred to as electrical resistivity, ρ, volume resistivity or specific electrical resistance, is a material property related to the degree of the material's resistance to electric current expressed in the SI units Ohm·m or Ohm·cm (Ω·m or Ω·cm, respectively). Volume resistivity is usually determined according to ASTM D-4496 standard test method. A low-resistivity material is a material which readily conducts electric current.

In context of the present invention, the term “thermal conductivity” refers to a material property quantifying a material's ability to conduct heat expressed in the SI units W·m⁻¹·K⁻¹ or W·cm⁻¹·K⁻¹. A material having high thermal conductivity is very efficient at conducting heat. A material's thermal conductivity is commonly determined by standard tests according to ASTM E 1461 or ISO 22007. Thermal conductivity can be measured in in-plane and through-plane mode.

In context of the present invention, the term “electromagnetic interference (EMI)” is a physical phenomenon that occurs when an external source affects an electrical circuit by electromagnetic induction, electrostatic coupling or conduction. EMI perturbs or even completely degrades the performance of an electric circuit. Correspondingly, in context of the present invention, the term “electromagnetic interference shielding” refers to a material's ability to reduce or even completely eliminate the negative impact of EMI on electric circuits. In this regard, in the context of the present invention, the term “EMI shielding efficiency (EMI SE)” refers to a material's EMI shielding performance, commonly expressed as the attenuation in decibel (dB) of an electromagnetic wave at a certain frequency. EMI SE can for example be determined by standard tests according to ASTM D-4935 at a specific frequency range or methods derived therefrom. In context of the present invention, EMI SE is measured according to ASTM D-4935 at a frequency of 10 to 1000 MHz or method derived therefrom as detailed in the paper E. Hariya and U. Massahiro, “Instruments for Measuring Shielding Effectiveness”, EMC 1984 Tokyo.

In context of the present invention, the terms “conductive additive” and “conductive filler” are used interchangeably and refer to materials that are added to a polymer, e.g. a compounding composition, polymer binder or a resin, to provide thermal and/or electrical conductivity to the polymer. Conductive additive or conductive fillers are known to the skilled person and can be, for example, carbonaceous or metal-based or hybrid materials in various forms such as powders, fibers, or flakes.

### Aspects of the Invention

In a first aspect, the present invention provides a composition comprising carbon black and expanded graphite. The composition of the invention is characterized by one or more of the following:

The composition of the present invention comprises carbon black in an amount of 3 to 40, preferably 5 to 35, more preferably 10 to 30, even more preferably 12 to 26, most preferably 13 to 18 wt.-% based on the total weight of the composition.

The composition of the present invention comprises expanded graphite in an amount of 3 to 50, preferably 3 to 40, more preferably 3 to 35, even more preferably 3 to 30, still more preferably 3.5 to 20, in particular more preferably 4 to 18, in particular still more preferably 5 to 17, most preferably 7 to 15 wt.-% based on the total weight of the composition.

The composition comprises carbon black and expanded graphite in a combined amount of 10 to 50, preferably 17 to 45, more preferably 19 to 40, even more preferably 20 to 35, still more preferably 22 to 34, in particular more preferably 24 to 31, most preferably 25 to 30 wt.-% based on the total weight of the composition.

The ratio of wt.-% based on the total weight of the composition of carbon black to expanded graphite in the composition of the present invention is in the range of 0.1 to 9, preferably 0.33 to 9, more preferably 0.4 to 9, even more preferably 0.4 to 7, still more preferably 0.4 to 5, in particular more preferably 0.4 to 3, in particular still more preferably 0.4 to 2, most preferably 0.6 to 1.7.

The composition of the present invention comprises carbon black characterized by a BET specific surface area measured according to ASTM D3037 under nitrogen of less than 950 m²·g⁻¹, preferably less than 850 m²·g⁻¹, more preferably less than 700 m²·g⁻¹, even more preferably less than 600 m²·g⁻¹, most preferably less than 500 m²·g⁻¹, in particular in the range of 40 to 800, preferably 50 to 800, more preferably 30 to 100, even more preferably 50 to 80, most preferably 60 to 70 m²·g⁻¹ and, optionally, one or more of a primary particle size measured according to ASTM D3849-14a of 10 to 60, preferably 15 to 55, more preferably 20 to 40, even more preferably 25 to 35 nm; and/or an oil absorption number OAN when measured according to ASTM D-2414 of less than 400 ml·g⁻¹, preferably less than 390 ml·g⁻¹, more preferably less than 380 ml·g⁻¹, even more preferably less than 370 ml·g⁻¹, most preferably less than 350 ml·g⁻¹, in particular in the range of 100 to 330, preferably 150 to 230, more preferably 170 to 210, even more preferably 180 to 200, most preferably 185 to 195 ml·g⁻¹.

The composition of the present invention comprises expanded graphite characterized by one or more of a particle size distribution D₉₀ when measured according to ISO 13220 of 5 to 1000, preferably 20 to 800, more preferably 30 to 700, even more preferably 50 to 600, still more preferably 70 to 500, in particular more preferably 80 to 250, most preferably 85 to 150 μm and/or a bulk density when measured according to ASTM D-7481 of 0.01 to 1.00, preferably 0.02 to 0.9, more preferably 0.05 to 0.7, even more preferably 0.1 to 0.55, still more preferably 0.13 to 0.50, in particular more preferably 0.16 to 0.45, most preferably 0.16 to 0.25 g·cm⁻³.

In a preferred embodiment, the composition of the present invention comprises (a) carbon black in an amount of 3 to 40, preferably 5 to 35, more preferably 10 to 30, even more preferably 12 to 26, most preferably 13 to 18 wt.-% based on the total weight of the composition; and (b) expanded graphite in an amount of 3 to 50, preferably 3 to 40, more preferably 3 to 35, even more preferably 3 to 30, still more preferably 3.5 to 20, in particular more preferably 4 to 18, in particular still more preferably 5 to 17, most preferably 7 to 15 wt.-% based on the total weight of the composition.

In another preferred embodiment, the composition of the present invention comprises (a) carbon black; and (b) expanded graphite, wherein the carbon black is characterized by a BET specific surface area measured according to ASTM D3037 under nitrogen of less than 950 m²·g⁻¹, preferably less than 850 m²·g⁻¹, more preferably less than 700 m²·g⁻¹, even more preferably less than 600 m²·g⁻¹, most preferably less than 500 m²·g⁻¹, in particular in the range of 40 to 800, preferably 50 to 800, more preferably 30 to 100, even more preferably 50 to 80, most preferably 60 to 70 m²·g⁻¹ and, optionally, one or more of a primary particle size measured according to ASTM D3849-14a of 10 to 60, preferably 15 to 55, more preferably 20 to 40, even more preferably 25 to 35 nm; and/or an oil absorption number OAN when measured according to ASTM D-2414 of less than 400 ml·g⁻¹, preferably less than 390 ml·g⁻¹, more preferably less than 380 ml·g⁻¹, even more preferably less than 370 ml·g⁻¹, most preferably less than 350 ml·g⁻¹, in particular in the range of 100 to 330, preferably 150 to 230, more preferably 170 to 210, even more preferably 180 to 200, most preferably 185 to 195 ml·g⁻¹ and/or wherein the expanded graphite characterized by one or more of a particle size distribution D90 when measured according to ISO 13220 of 5 to 1000, preferably 20 to 800, more preferably 30 to 700, even more preferably 50 to 600, still more preferably 70 to 500, in particular more preferably 80 to 250, most preferably 85 to 150 μm and/or a bulk density when measured according to ASTM D-7481 of 0.01 to 1.00, preferably 0.02 to 0.9, more preferably 0.05 to 0.7, even more preferably 0.1 to 0.55, still more preferably 0.13 to 0.50, in particular more preferably 0.16 to 0.45, most preferably 0.16 to 0.25 g·cm⁻³.

In yet another preferred embodiment, the composition of the present invention comprises carbon black and expanded graphite, wherein the ratio of wt.-% based on the total weight of the composition of carbon black to graphite is in the range of 0.1 to 9, preferably 0.33 to 9, more preferably 0.4 to 9, even more preferably 0.4 to 7, still more preferably 0.4 to 5, in particular more preferably 0.4 to 3, in particular still more preferably 0.4 to 2, most preferably 0.6 to 1.7 and wherein the carbon black is characterized by a BET specific surface area measured according to ASTM D-3037 under nitrogen of less than 950 m²·g⁻¹, preferably less than 850 m²·g⁻¹, more preferably less than 700 m²·g⁻¹, even more preferably less than 600 m²·g⁻¹, most preferably less than 500 m²·g⁻¹, in particular in the range of 40 to 800, preferably 50 to 800, more preferably 30 to 100, even more preferably 50 to 80, most preferably 60 to 70 m²·g⁻¹; and optionally, one or more of a primary particle size measured according to ASTM D-3849-14a of 10 to 60, preferably 15 to 55, more preferably 20 to 40, even more preferably 25 to 35 nm; and/or an oil absorption number OAN when measured according to ASTM D-2414 of less than 400 ml·g⁻¹, preferably less than 390 ml·g⁻¹, more preferably less than 380 ml·g⁻¹, even more preferably less than 370 ml·g⁻¹, most preferably less than 350 ml·g⁻¹, in particular in the range of 100 to 330, preferably 150 to 230, more preferably 170 to 210, even more preferably 180 to 200, most preferably 185 to 195 ml·g⁻¹ and/or wherein the expanded graphite is characterized by one or more of a particle size distribution D₉₀ when measured according to ISO 13220 of 5 to 1000, preferably 20 to 800, more preferably 30 to 700, even more preferably 50 to 600, still more preferably 70 to 500, in particular more preferably 80 to 250, most preferably 85 to 150 μm and/or a bulk density when measured according to ASTM D-3037 of 0.01 to 1.00, preferably 0.02 to 0.9, more preferably 0.05 to 0.7, even more preferably 0.1 to 0.55, still more preferably 0.13 to 0.50, in particular more preferably 0.16 to 0.45, most preferably 0.16 to 0.25 g·cm⁻³.

In other preferred embodiments, it is also provided, that compositions according to the present invention comprise one or more fillers selected from the group consisting of metal powder, metal flakes, glass fibers, silicon fibers, carbon-based fillers selected from the group consisting of carbon conductive additives, natural graphite, synthetic graphite, surface modified graphite, graphite nanoplatelets, multiwall carbon nanotubes, single wall carbon nanotube, carbon nanostructures, metal-coated graphite, and combinations thereof. Such fillers may be used to optimize and fine tune chemical and physical properties of the compositions.

In other preferred embodiments, it is also provided, that the compositions comprise a polymer, preferably, the polymer being selected from the from the group consisting of polyolefins, preferably the polyolefins being selected from polyethylene, polypropylene and combinations thereof, more preferably the polyolefins are polypropylene, polyamides, polymethylmethacrylate (PMMA), polyacetal, polycarbonate, polyvinyls, polyacrylonitrile, polybutadiene, polystyrene, polyacrylate, epoxy polymers, polyesters, polycarbonates, polyketones, polysulfones, unsaturated polyesters, polyurethanes, polycyclopentadienes, silicones, rubber, thermosets, thermoplastics, binders for coating and combinations thereof. This way, the composition of the present invention can be applied to a broad spectrum of polymers.

In a second aspect, the present invention provides a shaped article of composite material comprising the composition according to the invention as described hereinabove.

In a third aspect, the present invention provides a substrate coated with a coating comprising the composition of the invention.

The shaped article or the coating for the substrate of the present invention can comprise a polymer selected from the group consisting of polyolefins, preferably the polyolefins being selected from polyethylene, polypropylene and combinations thereof, more preferably the polyolefins are polypropylene, polyamides, polymethylmethacrylate (PMMA), polyacetal, polycarbonate, polyvinyls, polyacrylonitrile, polybutadiene, polystyrene, polyacrylate, epoxy polymers, polyesters, polycarbonates, polyketones, polysulfones, unsaturated polyesters, polyurethanes, polycyclopentadienes, silicones, rubber, thermosets, thermoplastics, binders for coating and combinations thereof.

In preferred embodiments of the shaped article or the coating for the substrate of the present invention, the carbon black and the expanded graphite are dispersed in the polymer. This provides for equal distribution of the conductive additives in the polymer and provides for particular good effects like EMI shielding efficiency or thermal conductivity.

In a fourth aspect, the present invention provides for use of the composition, the shaped article or the coated substrate according to the invention as described hereinabove for providing one or more of electro-magnetic interference (EMI) shielding measured according to ASTM D-4935 at a frequency of 10 to 1000 MHz or method derived therefrom as detailed in the paper E. Hariya and U. Massahiro, “Instruments for Measuring Shielding Effectiveness”, EMC 1984 Tokyo, wherein the EMI shielding is at least 20 dB, preferably at least 30 dB, more preferably at least 40 dB; volume resistivity measured according to ASTM D-4496, wherein the volume resistivity is less than 1000 Ohm·cm, preferably less than 100 Ohm·cm, more preferably less than 10 Ohm·cm, most preferably less than 1 Ohm·cm; and/or in-plane thermal conductivity measured according to ASTM E 1461, wherein the inplane thermal conductivity is greater than 0.5 W·m⁻¹K⁻¹, preferably greater than 0.7 W·m⁻¹K⁻¹, more preferably greater than 0.9 W·m⁻¹K⁻¹, in particular more preferably greater than 1.1 W·m⁻¹K⁻¹, even more preferably greater than 1.3 W·m⁻¹K⁻¹, still more preferably greater than 1.5 W·m⁻¹K⁻¹, in particular still more preferably greater than 1.7 W·m⁻¹K⁻¹, still more preferably greater than 2.0 W·m⁻¹K⁻¹, still more preferably greater than 2.5 W·m⁻¹K⁻¹, even more preferably greater than 3.0 W·m⁻¹K⁻¹, in particular even more preferably greater than 4.0 W·m⁻¹K⁻¹, in particular still more preferably greater than 5.0 W·m⁻¹K⁻¹, still more preferably greater than 6.0 W·m⁻¹K⁻¹, most preferably greater than 7.0 W·m⁻¹K⁻¹.

In a fifth aspect, the present invention provides for a method of providing electromagnetic interference (EMI) shielding measured according to standard test method ASTM D-4935 at a frequency of 10 MHz to 1000 MHz or method derived therefrom as detailed in the paper E. Hariya and U. Massahiro, “Instruments for Measuring Shielding Effectiveness”, EMC 1984 Tokyo in a polymeric composition using the composition, the shaped article or the coated substrate according to the invention as described hereinabove, wherein the EMI shielding is at least 20 dB, preferably at least 30 dB, more preferably at least 40 dB.

In a sixth aspect, the present invention provides for a method of providing volume resistivity when measured according to standard test method ASTM D-4496 in a polymeric composition using the composition, the shaped article or the coated substrate according to the invention as described hereinabove, wherein the volume resistivity is less than 1000 Ohm·cm, preferably less than 100 Ohm·cm, more preferably less than 10 Ohm·cm, most preferably less than 1 Ohm·cm.

In a seventh aspect, the present invention provides for a method of providing in-plane thermal conductivity measured according to ASTM E 1461 in a polymeric composition using the composition, the shaped article or the coated substrate according to the invention as described hereinabove, wherein the inplane thermal conductivity is greater than 0.5 W·m⁻¹K⁻¹, preferably greater than 0.7 W·m⁻¹K⁻¹, more preferably greater than 0.9 W·m⁻¹K⁻¹, in particular more preferably greater than 1.1 W·m⁻¹K⁻¹, even more preferably greater than 1.3 W·m⁻¹K⁻¹, still more preferably greater than 1.5 W·m⁻¹K⁻¹, in particular still more preferably greater than 1.7 W·m⁻¹K⁻¹, still more preferably greater than 2.0 W·m⁻¹K⁻¹, still more preferably greater than 2.5 W·m⁻¹K⁻¹, even more preferably greater than 3.0 W·m⁻¹K⁻¹, in particular even more preferably greater than 4.0 W·m⁻¹K⁻¹, in particular still more preferably greater than 5.0 W·m⁻¹K⁻¹, still more preferably greater than 6.0 W·m⁻¹K⁻¹, most preferably greater than 7.0 W·m⁻¹K⁻¹.

In further preferred embodiments, the use or the method of providing electromagnetic interference (EMI) shielding of the present invention improve EMI shielding by at least 10 dB, preferably at least 20 dB, more preferably at least 25 dB, even more preferably at least 30 dB, still more preferably at least 35 dB, in particular more preferably at least 40 dB, most preferably at least 45 dB, in particular by 10 to 80 dB, preferably 15 to 70 dB, more preferably 18 to 60 dB, in particular more preferably 20 to 55 dB, even more preferably 25 to 50 dB, in particular even more preferably 27 to 50 dB, still more preferably 30 to 50 dB, in particular still more preferably 31 to 45 dB, most preferably 35 to 42 dB when compared to a reference material not comprising carbon black, expanded graphite or any other conductive filler or additive, in particular a composition according to the invention as described hereinabove.

In further preferred embodiments, the use or the method of providing volume resistivity of the present invention reduce volume resistivity by a factor of 1.3 to 109, preferably 1.5 to 108, more preferably 2 to 107, in particular preferably 2 to 106, even more preferably 2 to 105, in particular even more preferably 3 to 105, still more preferably 3 to 104, in particular still more preferably 5 to 104, even more preferably 7 to 104, still more preferably 7 to 103, in particular even more preferably 10 to 103, in particular still more preferably 15 to 103, even more preferably 50 to 103, most preferably 102 to 103 when compared to a reference material not comprising carbon black, expanded graphite or any other conductive filler or additive, in particular a composition according to the invention as described hereinabove.

In further preferred embodiments, the use or the method of providing in-plane thermal conductivity of the present invention increase in-plane thermal conductivity by a factor of 2, preferably 3, more preferably 4, in particular preferably 5, even more preferably 6, in particular even more preferably 7, still more preferably 8, in particular still more preferably 9, still more preferably 10, even more preferably 12, in particular still more preferably 14, in particular even more preferably 16, still more preferably 18, even more preferably 20, in particular still more preferably 25, in particular still more preferably 30, even more preferably 40, most preferably 50 when compared to a reference material not comprising carbon black, expanded graphite or any other conductive filler or additive, in particular a composition according to the invention as described hereinabove.

In summary, the subject matter of the present invention as described hereinabove advantageously allows to optimize both the amount of conductive additives and desired properties of compositions such as electrical conductivity, EMI shielding efficiency and in-plane thermal conductivity without compromising rheological and mechanical properties.

It is intended that all matter contained in the above description should be interpreted as illustrative and not in a limiting sense. Thus, certain changes may be made in the compositions, uses and methods described above without departing from the scope of the present invention.

The invention will be further described by the following examples which illustrate the preparation of compositions and their corresponding properties, without limiting the invention.

### EXAMPLES

### Materials Used:

### Polymers:

Polypropylene, commercially available as “PP 412 MN40”;
Polyamide, commercially available as “Technyl C246”.

### Additives:

Conductive Carbon Black, commercially available as “Ensaco® 250G” from Imerys characterized by an oil absorption number (OAN) of 190 mL/100 g and a BET specific surface area under nitrogen of 65 m²/g;
Extra-Conductive Carbon Black, commercially available as “Ensaco® 350G” from Imerys characterized by an OAN of 320 mL/100 g and a BET specific surface area under nitrogen of 770 m²/g;
Expanded graphite (high aspect ratio graphite), commercially available as “Timrex® C-THERM™ 011” from Imerys characterized by a particle size distribution of D₉₀=90 μm;
Expanded graphite (high aspect ratio graphite), commercially available as “Timrex® C-THERM™ 301” from Imerys characterized by a particle size distribution of D₉₀=30 μm;
Expanded graphite (high aspect ratio graphite), commercially available as “Timrex® C-THERM™ MAX HD” from Imerys characterized by a particle size distribution of D₉₀>400 μm;
Synthetic graphite (low aspect ratio primary synthetic graphite), commercially available as “Timrex® SFG44” from Imerys characterized by a BET specific surface area of ca. 5 m²/g and a particle size distribution of D₉₀=50 μm;
Synthetic graphite (low aspect ratio primary synthetic graphite), commercially available as “Timrex® KS44” from Imerys characterized by a BET specific surface area under nitrogen of ca. 9 m²/g and a particle size distribution of D₉₀=46 μm
Carbon fiber, commercially available as “Tenax A HT P802 3 mm” from Teijin characterized by a fiber diameter of 7 μm and a pellet length of 8 mm.

### Methods and Equipment Used:

The melt flow rate (MFR) is measured via a Melt Flow Tester, CEAST according to norm ISO 1133 at 5 kg and 230° C. Other conditions used for the MFR measurements are indicated.

The volume resistivity is measured using a Loresta GX device from Nittoseiko-Mitsubishi, using the 4 points ASP Probe according to norm ASTM D4496.

EMI shielding was tested on 2.3-2.4 mm thick compressed plaques (150×150 mm² size) at frequencies in the range from 10 MHz to 1 GHz according to the “TEM t cell” method which is derived from ASTM D 4935 (details to be found in the paper E. Hariya and U. Massahiro, “Instruments for Measuring Shielding Effectiveness”, EMC 1984 Tokyo). For all samples having attenuation above 25 dB, a correction factor corresponding to the theoretical value of the empty TEM t cell as derived from the equivalent circuit was applied.

The thermal conductivity is measured using Laser Flash LFA 447 from Netzsch according to norm ASTM E 1461 at a temperature of 23° C. The measurements are made both in-plane and through-plane direction with regard to the material flow during the plaque filling stage.

The tensile properties are measured with an Instron Dynamometer 5966 according to ISO 527.

### Tested Formulations:

A) Compositions with Polypropylene (PP)
A-1) PP Compositions with Blends of CB and EG

The polypropylene compositions listed in Table 1.1 were prepared with a final loading of conductive additives of 30 wt.-% based on the total weight of the composition with different blends of carbon black (Ensaco® 250G from Imerys with OAN=190 mL/g and BET specific surface area under nitrogen of 65 m²/g) and expanded graphite (Timrex® C-THERM™ 011 from Imerys with D₉₀=90 μm)

TABLE 1.1
Samples with polypropylene and a conductive
additive loading (filler loading) of 30 wt.-% with
different blends of carbon black and expanded graphite.

| | CB¹⁾/ | | EG²⁾/ | | |
|---|---|---|---|---|---|
| Sample | wt.-% | %* | wt.-% | %* | CB¹⁾:EG^{2)#} |
| PP-1 | 30 | 100 | 0 | — | — |
| PP-2 | 26.2 | 87.3 | 3.8 | 12.7 | 6.9 |
| PP-3 | 22.5 | 75 | 7.5 | 25 | 3 |
| PP-4 | 18.7 | 62 | 11.3 | 38 | 1.65 |
| PP-5 | 15 | 50 | 15 | 50 | 1 |
| PP-6 | 11.3 | 38 | 18.7 | 62 | 0.6 |
| PP-7 | 7.5 | 25 | 22.5 | 75 | 0.33 |
| PP-8 | 3.8 | 12.7 | 26.2 | 87.3 | 0.15 |
| PP-9 | 0 | — | 30 | 100 | — |

*% of total filler content;
^{#}wt.-% ratio of carbon black (CB) and expanded graphite (EG)
¹⁾Carbon black = Ensaco ® 250G″ from Imerys with OAN = 190 mL/g and BET specific surface area under nitrogen of 65 m²/g;
²⁾Expanded graphite = Timrex ® C-THERM ™ 011 from Imerys with D₉₀ = 90 μm;

A-2) PP Compositions with Further Blends of Conductive Fillers

For comparative tests, formulations with a final loading of conductive additives of 30 wt.-% based on the total weight of the composition (with the exception of sample PP-12 which only has 22.5 wt.-% based on the total weight of the composition) with different blends of different kinds of carbon black (Ensaco® 250G from Imerys with OAN=190 mL/g and BET specific surface area under nitrogen of 65 m²/g, or Ensaco® 350G from Imerys with OAN of 320 mL/100 g and BET specific surface area under nitrogen of 770 m²/g) and different kinds of expanded graphite (Timrex® C-THERM™ Oil from Imerys with D₉₀=90 μm or Timrex® C-THERM™ 301 from Imerys with D₉₀=30 μm or Timrex® C-THERM™ MAX HD from Imerys with D₉₀>400 μm; see samples PP-10 to PP-12), optionally with carbon fibers (Tenax A HT P802 3 mm from Teijin with fiber diameter of 7 μm and pellet length of 8 mm) as additional conductive additives (samples PP-13 to PP-14) were prepared, see Table 1.2.

TABLE 1.2
Samples with further blends of conductive fillers.

| | | | EG | | | |
|---|---|---|---|---|---|---|
| | | | and/or | | | |
| | CB/ | | CF/ | | wt.-% | Resistivity^{§}/ |
| Sample | wt.-% | %* | wt.-% | %* | ratio^{#} | Ohm · cm |
| PP-10 | 15¹⁾ | 50 | 15³⁾ | 50 | 1 | 1.37 · E0 |
| PP-11 | 15¹⁾ | 50 | 15⁴⁾ | 50 | 1 | 2.13 · E0 |
| PP-12^{‡} | 7.5⁵⁾ | 0.33 | 15 | 0.67^{‡} | 2 | 3.13 · E0 |
| PP-13 | 15¹⁾ | 50 | 15 (CF) ⁶⁾ | 50 | 1 | 0.41 · E0 |
| PP-14 | 10¹⁾ | 0.33 | 10²⁾ | 0.33 | 1 | 1.99 · E0 |
| | | | 10 (CF) ⁶⁾ | 0.33 | | |

*% of total filler content;
^{#}wt-% ratio of carbon black (CB) to: i) expanded graphite (EG) or ii) EG + carbon fiber (CF) or iii) CF alone;
^{§}Resistivity expressed as average of parallel and perpendicular mode measurements;
^{‡}Total amount of filler for sample PP-12 = 22. 5 wt.-%;
¹⁾Carbon black = Ensaco ® 250G″ from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Expanded graphite = Timrex ® C-THERM ™ 301 from Imerys with D₉₀ = 30 μm;
⁴⁾Expanded graphite = Timrex ® C-THERM ™ MAX HD from Imerys with D₉₀ > 400 μm;
⁵⁾Carbon black = extra-conductive carbon black Ensaco ® 350G from Imerys with OAN of 320 mL/100 g and BET specific surface area under nitrogen of 770 m²/g; total loading of conductive additives only 22.5 wt.-% based on the total weight of the composition;
⁶⁾ Carbon fiber (CF) = Tenax A HT P802 3 mm from Teijin with fiber diameter of 7 μm and pellet length of 8 mm.

A-3) PP Compositions with Blends of CB and Synthetic Graphite

For comparative tests, formulations with a final loading of conductive additives of 30 wt.-% based on the total weight of the composition with different blends of carbon black (Ensaco® 250G″ from Imerys with OAN=190 mL/g and BET specific surface area under nitrogen of 65 m²/g) and synthetic graphite (“Timrex® SFG44 Primary Synthetic Graphite” from Imerys characterized by a BET specific surface area of ca. 5 g/m² and a particle size distribution of D₉₀=50 μm) were prepared, see Table 1.3.

TABLE 1.3
Samples for comparative tests with synthetic
graphite (SG) instead of expanded graphite (EG).

| | CB¹⁾/ | | SG²⁾/ | | |
|---|---|---|---|---|---|
| Sample | wt.-% | %* | wt.-% | %* | CB¹⁾:SG^{2)#} |
| PP-15 | 15 | 50 | 15 | 50 | 1 |
| PP-16 | 7.5 | 25 | 22.5 | 75 | 0.33 |
| PP-17 | 0 | 0 | 30 | 100 | 0 |

¹⁾Carbon black = Ensaco ® 250G from Imerys with OAN = 190 mL/g and BET specific surface area under nitrogen of 65 m²/g;
²⁾Synthetic graphite = Timrex ® SFG44 Primary Synthetic Graphite from Imerys with BET specific surface area of ca. 5 m²/g and D₉₀ = 50 μm;
*% of total filler content;
^{#}wt.-% ratio of carbon black (CB) and expanded graphite (SG)

B) Compositions with Polyamide (PA)

The polyamide compositions listed in Table 2 were prepared with different final loadings of conductive additives and with different single component additives or blends of carbon black (Ensaco® 250G from Imerys with OAN=190 mL/g and BET specific surface area under nitrogen of 65 m²/g) and expanded graphite (Timrex® C-THERM™ 011 from Imerys with D90=90 μm). For comparative tests, formulations with synthetic graphite (“Timrex® KS44” from Imerys with a BET specific surface area under nitrogen of ca. 9 m²/g and D₉₀=46 μm) were prepared.

TABLE 2
Samples for polyamide compositions with conductive
fillers of single-component additives and binary
blends of carbon black and expanded graphite.

| | | Total amount filler/ |
|---|---|---|
| Sample | Filler type | wt.-% |
| PA-1 | CB¹⁾ | 5 |
| PA-2 | | 10 |
| PA-3 | | 15 |
| PA-4 | | 20 |
| PA-5 | EG²⁾ | 5 |
| PA-6 | | 10 |
| PA-7 | | 15 |
| PA-8 | | 20 |
| PA-9 | | 30 |
| PA-10 | SG³⁾ | 10 |
| PA-11 | | 20 |
| PA-12 | | 30 |
| PA-13 | Blend of | 25 |
| | CB¹⁾ + EG²⁾ | (12.5 CB + 12.5 EG) |

¹⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Synthetic graphite = Timrex ® KS44 from Imerys with a BET specific surface area under nitrogen of ca. 9 m²/g and D₉₀ = 46 μm.

### Example 1: Preparation of the Composites

Samples PP-1 through PP-17 and PA-1 through PA-13 described above are used as composites in at least some of the following examples, and the composites in the following examples are prepared by melt extrusion using a twin screw extruder, Leistritz ZSE 27 mm, with an L/D ratio of 48, equipped with two side feeders. The polymer melt temperature is set at 240° C., the screw speed are fixed at 200 rpm and the total output is 15 kg/h. The Polypropylene, Sabic, PP 412 MN40, is added in the main feeder. The conductive additives are added in the polymer melt using one or two side feeders fed by gravimetric feeders. The composites are extruded via a die, cooled down via water batch, granulated using rotating and cutting blades.

### Example 2: Preparation of the Test Specimen (Plaques)

The samples for volume resistivity, mechanical tests, and thermal conductivity are prepared by injection molding using a Billion Proxima 50T.

The samples for EMI shielding tests are compressed using a LabTech press LPS20. Plaques of 150×150×2.4 mm² are prepared.

### Example 3: Measurement of the Viscosity (MFI)

The inventors of the present invention found that blends of carbon black and expanded graphite according to the present invention advantageously provide for acceptable rheologic properties:

### 3.1. Viscosity (MFI) Data for Polypropylene Compositions

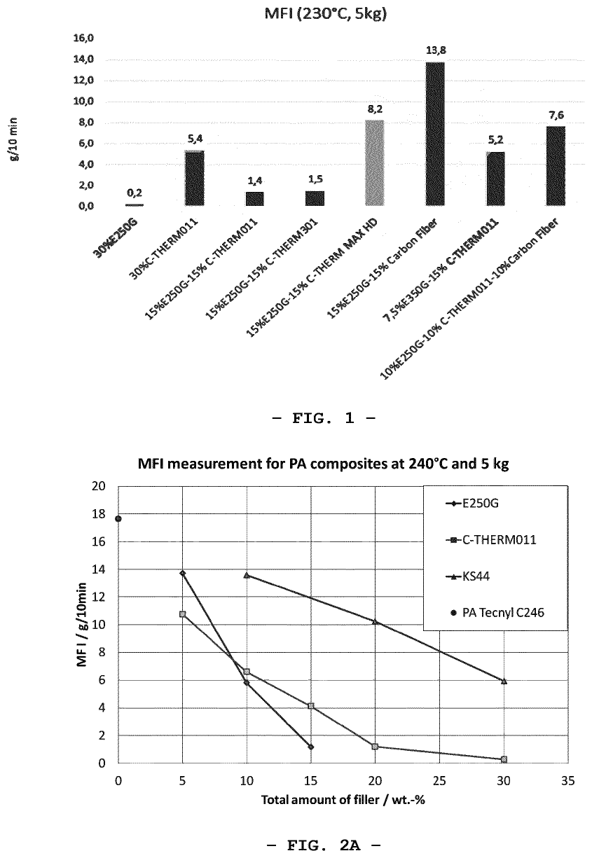

TABLE 3.1
Viscosity (MFI) data for polypropylene compositions
with blends of carbon black and expanded graphite
(samples PP-3.1 to PP-3.5) and compositions with
blends of different kinds of carbon black and
different kinds of expanded graphite, optionally
with carbon fibers as additional conductive
additives (samples PP-3.6 to PP-3.10), also see FIG. 1.

| | | | | | | Viscosity |
|---|---|---|---|---|---|---|
| | | | | | | (MFI)/ |
| | | | | | | g/10 min) |
| | CB/ | | EG/ | | wt.-% | @ 230° C./ |
| Sample | wt.-% | %* | wt.-% | %* | ratio ^{#} | 5 kg |
| Ctrl. | 0 | — | 0 | — | — | 37^{§)} |
| PP-3.1 | 30 ¹⁾ | 100 | 0 | — | — | 0.2 |
| PP-3.2 | 22.5¹⁾ | 75 | 7.5 ²⁾ | 25 | 3 | 0.5 |
| PP-3.3 | 15 ¹⁾ | 50 | 15 ²⁾ | 50 | 1 | 1.4 |
| PP-3.4 | 7.5 ¹⁾ | 25 | 22.5²⁾ | 75 | 0.33 | 2.2 |
| PP-3.5 | 0 | — | 30 ²⁾ | 100 | — | 5.4 |
| PP-3.6 | 15 ¹⁾ | 50 | 15 ³⁾ | 50 | 1 | 1.5 |
| PP-3.7 | 15 ¹⁾ | 50 | 15 ⁴⁾ | 50 | 1 | 8.2 |
| PP-3.8^{‡} | 7.5 ⁵⁾ | 33 | 15 ²⁾ | 67 | 1 | 5.2 |
| PP-3.9 | 15 ¹⁾ | 50 | 15 | 50 | — | 13.8 |
| | | | (CF) ⁶⁾ | | | |
| PP- | 10 ¹⁾ | 33 | 10 ²⁾ | 0.33 | 1 | 7.6 |
| 3.10⁷⁾ | | | 10 | 0.33 | | |
| | | | (CF) ⁶⁾ | | | |

*% of total filler content;
^{#} wt.-% ratio of carbon black (CB) to: i) expanded graphite (EG) or ii) EG + carbon fiber (CF) or iii) CF alone;
^{‡}Total amount of filler for sample PP-3.8 = 22.5 wt.-%;
^{§)}measured at 230° C./2.16 kg;
¹⁾ Carbon black = Ensaco® 250G from Imerys with OAN = 190 mL/g and BET specific surface area under nitrogen of 65 m²/g;
²⁾ Expanded graphite = Timrex ® C-THERM ™ 011 from Imerys with D₉₀ = 90 μm;
³⁾ Expanded graphite = Timrex ® C-THERM ™ 301 from Imerys with D₉₀ = 30 μm;
⁴⁾ Expanded graphite = Timrex ® C-THERM ™ MAX HD from Imerys with D₉₀ > 400 μm;
⁵⁾ Carbon black = extra-conductive carbon black Ensaco ® 350G from Imerys with OAN of 320 mL/100 g and BET specific surface area under nitrogen of 770 m²/g; total loading of conductive additives only 22.5 wt.-% based on the total weight of the composition;
⁶⁾ Carbon fiber = Tenax A HT P802 3 mm from Teijin with fiber diameter of 7 μm and pellet length of 8 mm.
⁷⁾Conductive additives = 10 wt.-% CB (Ensaco ® 250G), 10 wt.-% EG (Timrex ® C-THERM ™ 011), 10 wt.-% carbon fiber (Tenax A HT P802).

From the data presented in Table 3.1 and FIG. 1, it can be derived that the viscosity increases with increasing amounts of carbon black in the conductive additive (the higher the amount of carbon black in the conductive additive, the lower the MFI) and vice versa that the viscosity decreases with increasing amounts of expanded graphite (the higher the amount of expanded graphite in the conductive additive, the higher the MFI).

Also, from comparing samples PP-3.3, PP-3.6, and PP-3.7 with CB:EG-ratios of 1 with different types of expanded graphite it can be derived that expanded graphite Timrex® C-THERM™ 011 from Imerys with D₉₀=90 μm provides for the lowest MFI (highest viscosity) in blends with Ensaco® 250 G carbon black.

Further, conductive additive blends with carbon fiber provide for lower viscosities (higher MFI) than blends without carbon fiber.

### 3.2. Viscosity (MFI) Data for Polyamide Compositions

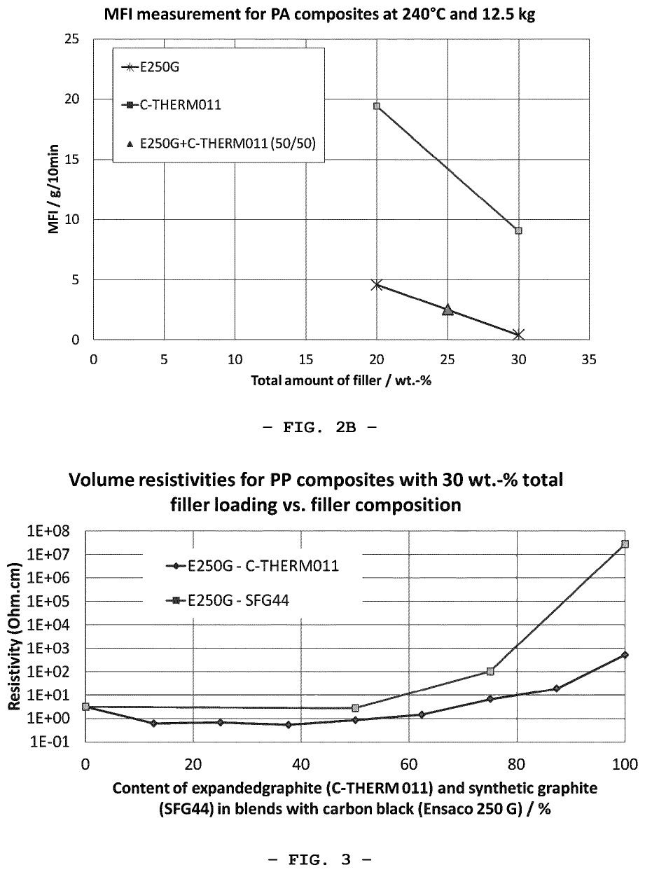

TABLE 3.2
Viscosity (MFI) data for polyamide compositions
with conductive fillers of single-component additives
and binary blends of carbon black and expanded graphite,
also see FIG. 2A and FIG. 2B.

| | | Total amount | Viscosity (MFI)/ |
|---|---|---|---|
| | | of filler/ | g/10 min |
| Sample | Filler type | wt.-% | @ 240° C./5 kg |
| Ctrl. | — | 0 | 17.63 |
| PA-3.1 | CB¹⁾ | 5 | 13.72 |
| PA-3.2 | | 10 | 5.81 |
| PA-3.3 | | 15 | 1.17 |
| PA-3.4 | EG²⁾ | 5 | 10.76 |
| PA-3.5 | | 10 | 6.59 |
| PA-3.6 | | 15 | 4.13 |
| PA-3.7 | | 20 | 1.20 |
| PA-3.8 | | 30 | 0.27 |
| PA-3.9 | SG³⁾ | 10 | 13.60 |
| PA-3.10 | | 20 | 10.23 |
| PA-3.11 | | 30 | 5.92 |
| | | Total amount | Viscosity (MFI)/ |
| | | of filler/ | g/10 min |
| Sample | Filler type | wt.-% | @ 240° C./10 kg |
| PA-3.12 | CB¹⁾ | 20 | 2.31 |
| PA-3.13 | Blend of | 25 | 1.45 |
| | CB¹⁾ + EG²⁾ | (12.5 CB:12.5 EG) | |
| | | Total amount | Viscosity (MFI)/ |
| | | of filler/ | g/10 min |
| Sample | Filler type | wt.-% | @ 240° C./12.5 kg |
| PA-3.14 | CB¹⁾ | 20 | 4.58 |
| PA-3.15 | | 30 | 0.39 |
| PA-3.16 | EG²⁾ | 20 | 19.40 |
| PA-3.17 | | 30 | 9.04 |
| PA-3.18 | Blend of | 25 | 2.53 |
| | CB¹⁾ + EG²⁾ | (12.5 CB + 12.5 EG) | |

^{#}) wt.-% ratio of carbon black (CB) and expanded graphite (EG);
1⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Synthetic graphite = Timrex ® KS44 from Imerys with D₉₀ = 46 μm.

The inventors of the present invention found that polyamide compositions with more than 10 wt.-% carbon black (Ensaco® 250 G) are very viscous and, thus, more difficult to handle compared with polyamide compositions with lower carbon black loadings or other fillers than carbon black such as expanded graphite or synthetic graphite. Against this background, for measuring the viscosity (determined as MFI) of samples PA-3.12 to PA-3.15 and sample PA-3.18) higher sample loadings of 10 and 12.5 kg, respectively, were necessary.

Also, the inventors of the present invention found that sample PA-3.15 with 30 wt.-% carbon black (Ensaco® 250 G) could not be injection molded and that polyamide compositions with 15 wt.-% carbon black (Ensaco® 250 G) and 15 wt.-% expanded graphite (Timrex® C-THERM™ 011) could not be extruded any more.

According to the data presented in Table 3.2 above, at corresponding filler loadings, samples with 10% wt or more expanded graphite show lower viscosity (higher MFI) compared with samples comprising exclusively carbon black at same loading.

### Example 4: Measurement of the Volume Resistivity

The inventors of the present invention found that blends of carbon black and expanded graphite according to the present invention advantageously provide for superior conductivity:

### 4.1. Volume Resistivity Data for Polypropylene Compositions

Volume resistivities of polypropylene compositions with blends of carbon black and expanded graphite as conductive additives at an additive loading of 30 wt.-% based on the total weight of the composition were measured (samples PP-4.1 to PP-4.9). For comparative tests, volume resistivities of polypropylene compositions with blends of carbon black and synthetic graphite as conductive additives at an additive loading of 30 wt.-% based on the total weight of the composition were measured (samples PP-4.10 to PP-4.12), see Table 4.1.

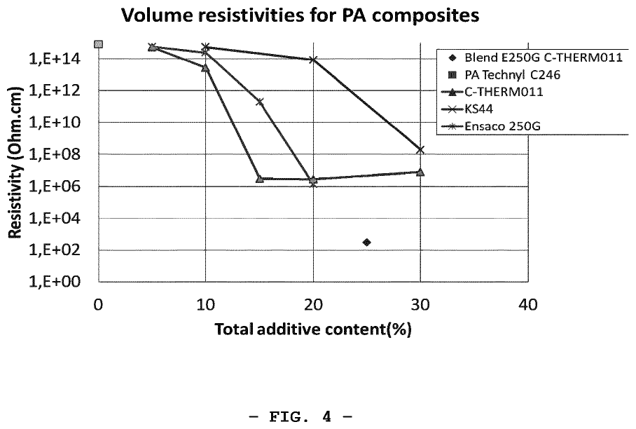

TABLE 4.1
Volume resistivity data for polypropylene compositions
with blends of carbon black and expanded graphite
(samples PP-4.1 to PP-4.9) and compositions with blends of
different kinds of carbon black and different kinds of expanded
graphite (samples PP-4.10 to PP-4.12), optionally with carbon
fibers as additional conductive additives (samples PP-4.13 to
PP-4.14) or with synthetic graphite instead of expanded
graphite (samples PP-4.15 to PP-4.17), also see FIG. 3.

| | CB/ | | EG/ | | wt.-% | Resistivity^{§}/ |
|---|---|---|---|---|---|---|
| Sample | wt.-% | %* | wt.-% | %* | ratio ^{#} | Ohm · cm |
| Ctrl. | 0 | — | 0 | — | — | 1.99 · E+14 |
| PP-4.1 | 30 ¹⁾ | 100 | 0 | — | — | 2.30 · E0 |
| PP-4.2 | 26.2¹⁾ | 87.3 | 3.8 ²⁾ | 12.7 | 6.9 | 6.67 · E−01 |
| PP-4.3 | 22.5¹⁾ | 75 | 7.5 ²⁾ | 25 | 3 | 6.68 · E−01 |
| PP-4.4 | 18.7¹⁾ | 62 | 11.3 ²⁾ | 38 | 1.65 | 6.00 · E−01 |
| PP-4.5 | 15 ¹⁾ | 50 | 15 ²⁾ | 50 | 1 | 9.23 · E−01 |
| PP-4.6 | 11.3¹⁾ | 38 | 18.7 ²⁾ | 62 | 0.6 | 1.47 · E0 |
| PP-4.7 | 7.5 ¹⁾ | 25 | 22.5 ²⁾ | 75 | 0.33 | 6.65 · E0 |
| PP-4.8 | 3.8 ¹⁾ | 12.7 | 26.2 ²⁾ | 87.3 | 0.15 | 1.88 · E+01 |
| PP-4.9 | 0 | — | 30 ²⁾ | 100 | — | 5.85 · E+02 |
| PP-4.10 | 15 ¹⁾ | 50 | 15³⁾ | 50 | 1 | 1.37 · E0 |
| PP-4.11 | 15 ¹⁾ | 50 | 15⁴⁾ | 50 | 1 | 2.13 · E0 |
| PP-4.12^{‡} | 7.5⁵⁾ | 0.33 | 15 ²⁾ | 0.67^{‡} | 2 | 3.13 · E0 |
| PP-4.13 | 15 ¹⁾ | 50 | 15 (CF) ⁶⁾ | 50 | 1 | 0.41 · E0 |
| PP-4.14 | 10¹⁾ | 0.33 | 10²⁾ | 0.33 | 1 | 1.99 · E0 |
| | | | 10 (CF) ⁶⁾ | 0.33 | | |
| | CB/ | | SG⁷⁾/ | | CB¹⁾: | Resistivity^{§}/ |
| Sample | wt.-% | %* | wt.-% | %* | SG^{7)#} | Ohm · cm |
| PP-4.15 | 15 ¹⁾ | 50 | 15 | 50 | 1 | 2.80 · E0 |
| PP-4.16 | 7.5 ¹⁾ | 25 | 22.5 | 75 | 0.33 | 1.03 · E+02 |
| PP-4.17 | 0 | 0 | 30 | 100 | 0 | 2.85 · E+07 |

*% of total filler content;
^{#} wt.-% ratio of carbon black (CB) to: i) expanded graphite (EG) or ii) EG + carbon fiber (CF) or iii) CF alone; ;
^{§}Resistivity expressed as average of parallel and perpendicular mode measurements;
^{‡}Total amount of filler for sample PP-4.12 = 22.5 wt.-%;
¹⁾ Carbon black = Ensaco ® 250G″ from Imerys with OAN = 190 mL/g and BET specific surface area under nitrogen of 65 m²/g;
²⁾ Expanded graphite = Timrex ® C-THERM ™ 011 from Imerys with D₉₀ = 90 μm;
³⁾Expanded graphite = Timrex ® C-THERM ™ 301 from Imerys with D₉₀ = 30 μm;
⁴⁾Expanded graphite = Timrex ® C-THERM ™ MAX HD from Imerys with D₉₀ > 400 μm;
⁵⁾Carbon black = extra-conductive carbon black Ensaco ® 350G from Imerys with OAN of 320 mL/100 g and BET specific surface area under nitrogen of 770 m²/g; total loading of conductive additives only 22.5 wt.-% based on the total weight of the composition;
⁶⁾ Carbon fiber = Tenax A HT P802 3 mm from Teijin with fiber diameter of 7 μm and pellet length of 8 mm.
⁷⁾Synthetic graphite = Synthetic graphite = Timrex ® SFG44 Primary Synthetic Graphite from Imerys with BET specific surface area of ca. 5 m²/g and D₉₀ = 50 μm.

From Table 4.1 and FIG. 3 it can be derived that samples PP-4.5 (CB:EG=1), PP-4.3 (CB:EG=3), PP-4.2 (CB:EG=6.9) and PP-4.4 (CB:EG=1.65) provide for the lowest volume resistivities of 9.23·E-1 Ohm·cm, 6.68·E-1 Ohm·cm, 6.0·E-1 Ohm·cm, and 6.67·E-1, respectively. Also, as can be derived from the Table 4.1 above, at equal additive loadings of 30 wt.-% and ratios of carbon black to graphite of 1, samples with blends of carbon black and expanded graphite provide for significantly lower volume resistivities compared to samples with blends of carbon black and synthetic graphite: For example, at a carbon black to graphite ratio of 1, samples PP-4.5, PP-4.10 and PP-4.11 with expanded graphite provide for volume resistivities of 9.23·E-1 Ohm·cm, 1.37·E0 Ohm·cm, and 2.13·E0 Ohm·cm, respectively which are significantly lower compared with a volume resistivity of 2.8·E0 Ohm·cm measured for sample PP-4.15 with synthetic graphite.

In particular, it can be derived from Table 4.1 and FIG. 3 that conductive additives with blends of carbon black and expanded graphite provide for lower volume resistivities compared with fillers of single conductive additives, i.e. exclusively carbon black or exclusively expanded graphite. This result suggests a synergistic effect of carbon black and expanded graphite on volume resistivity.

### 4.2. Volume Resistivity Data for Polyamide Compositions

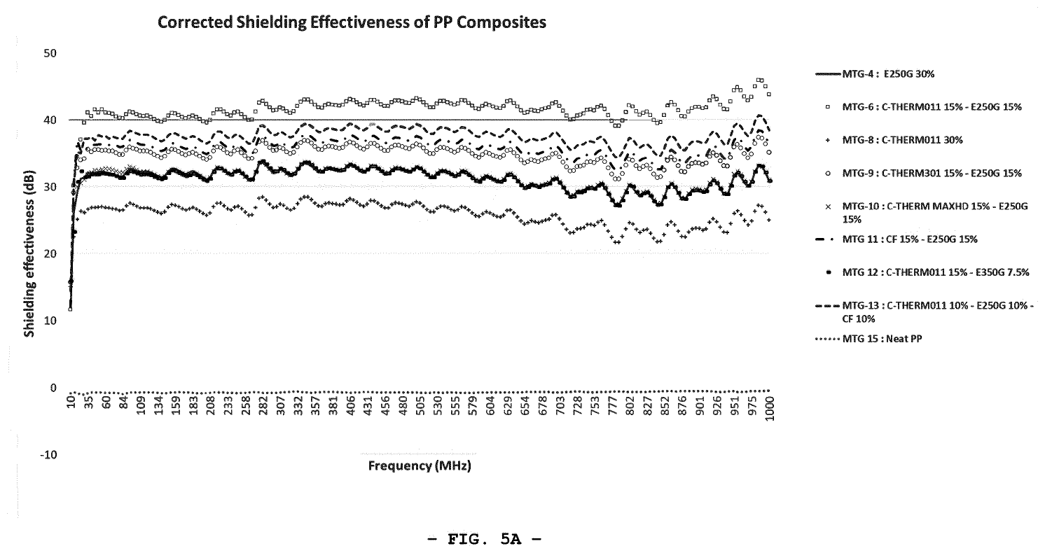

TABLE 4.2
Volume resistivity data for polyamide compositions
with conductive fillers of single-component additives
and binary blends of carbon black and expanded
graphite, also see FIG. 4.

| | | Total | | |
|---|---|---|---|---|
| | | amount | | |
| | Filler | filler/ | Resistivity/ | St. dev./ |
| Sample | type | wt.-% | Ohm · cm | Ohm · cm |
| Ctrl. | — | 0 | 8.07·E+14 | 3.73·E+14 |
| PA-4.1 | CB¹⁾ | 5 | 5.78 ·+ 14 | 3.22·E+13 |
| PA-4.2 | | 10 | 2.43·E+14 | 3.46·E+13 |
| PA-4.3 | | 15 | 1.96·E+11 | 1.46·E+11 |
| PA-4.4 | | 20 | 1.37·E+06 | 2.51·E+06 |
| PA-4.5 | EG²⁾ | 5 | 5.30·E+14 | 3.90·E+14 |
| PA-4.6 | | 10 | 2.60·E+13 | 2.84·E+13 |
| PA-4.7 | | 15 | 3.02·E+06 | 2.85·E+06 |
| PA-4.8 | | 20 | 2.77·E+06 | 1.17·E+06 |
| PA-4.9 | | 30 | 7.69·E+06 | 1.44·E+07 |
| PA-4.10 | SG³⁾ | 10 | 5.47·E+14 | 2.06·E+14 |
| PA-4.11 | | 20 | 8.45·E+13 | 1.98·E+13 |
| PA-4.12 | | 30 | 1.92·E+08 | 1.20·E+08 |
| PA-4.13 | Blend of | 25 | 2.93·E+02 | 4.62·E+02 |
| | CB¹⁾ + EG²⁾ | (12.5 CB + | | |
| | | 12.5 EG) | | |

¹⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Synthetic graphite = Timrex ® KS44 from Imerys with a BET specific surface area under nitrogen of ca. 9 m²/g and D₉₀ = 46 μm.

As can be derived from Table 4.2 and FIG. 4, for polyamide samples with a single conductive additive, volume resistivities decrease with increasing additive amount. This effect is more pronounced for samples comprising carbon black and/or expanded graphite compared with samples comprising synthetic graphite. Most importantly, the inventors of the present invention surprisingly found that blends of carbon black and expanded graphite, in particular with a ratio of carbon black to expanded graphite of 1 at a total filler loading of 25 wt.-% and partial amounts of 12.5 wt.-% carbon black (Ensaco® 250 G) and 12.5 wt. % expanded graphite (Timrex® C-THERM™ 011), respectively, provided for volume resistivities of four magnitudes lower compared to corresponding polyamide compositions with single conductive additives. This result suggests a synergistic effect of carbon black and expanded graphite on volume resistivity.

### Example 5: Measurement of the EMI Shielding Efficiency of Polypropylene Compositions

The inventors of the present invention found that blends of carbon black and expanded graphite according to the present invention advantageously provide for superior EMI shielding:

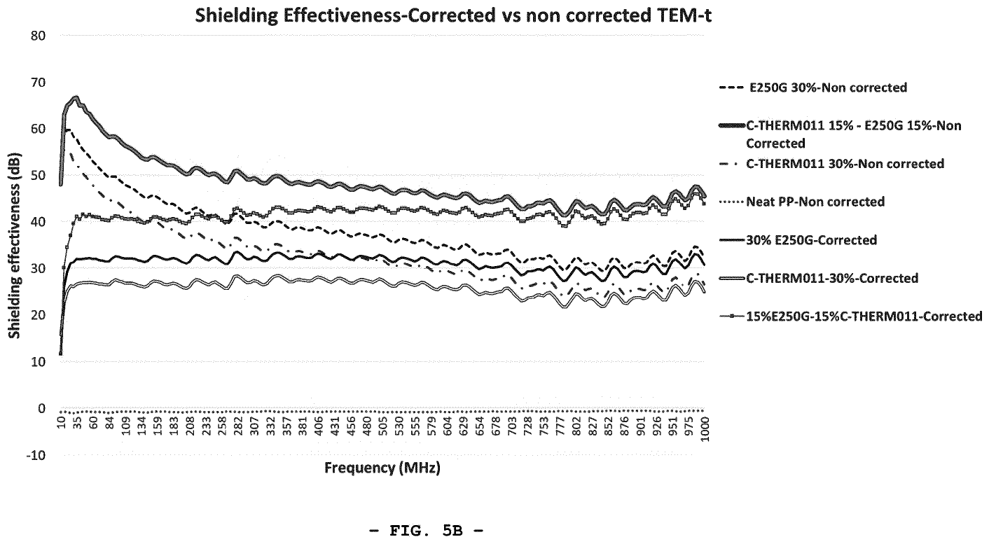

EMI shielding data were obtained for polypropylene compositions at a frequency of 10 MHz to 1000 MHz. Selected data points for corrected EMI shielding efficiency (attenuation) in dB are reproduced in Table 5 below. FIG. 5A is a plot of corrected and FIG. 5B is a plot of corrected and non-corrected EMI shielding efficiency (attenuation) vs. frequency taking more data points into account not shown in Table 5.

TABLE 5
EMI shielding data for polypropylene compositions
with blends of carbon black and expanded graphite (samples
PP-5.1 to PP-5.5) and compositions with blends of different
kinds of carbon black and different kinds of expanded graphite
(samples PP-5.6 to PP-5.8), optionally with additional carbon
fibers as conductive additives (samples PP-5.9 to PP-5.10),
also see FIG. 5A and FIG. 5B.

| | | | | | | EMI shielding | |
|---|---|---|---|---|---|---|---|
| | CB/ | | EG/ | | wt.-% | Frequ./ | EMI SE/ |
| Sample | wt.-% | %* | wt.-% | %* | ratio^{#} | MHz | dB (σ) |
| Ctrl. | 0 | — | 0 | — | — | 10 | −1 (±0.05) |
| | | | | | | 50 | −1 (±0.04) |
| | | | | | | 104 | −1 (±0.03) |
| | | | | | | 203 | −1 (±0.03) |
| | | | | | | 401 | −1 (±0.04) |
| | | | | | | 604 | −1 (±0.03) |
| | | | | | | 802 | −1 (±0.03) |
| | | | | | | 1000 | −1 (±0.02) |
| PP-5.1 | 30¹⁾ | 100 | 0 | — | — | 10 | 12 (±5.42) |
| | | | | | | 50 | 32 (±0.35) |
| | | | | | | 104 | 32 (±0.08) |
| | | | | | | 203 | 31 (±0.08) |
| | | | | | | 401 | 33 (±0.05) |
| | | | | | | 604 | 31 (±0.08) |
| | | | | | | 802 | 30 (±0.12) |
| | | | | | | 1000 | 31 (±0.15) |
| PP-5.2 | 22.5¹⁾ | 75 | 7.5²⁾ | 25 | 3 | 10 | 18 (±7.59) |
| | | | | | | 50 | 38 (±0.71) |
| | | | | | | 104 | 39 (±0.34) |
| | | | | | | 203 | 38 (±0.35) |
| | | | | | | 401 | 40 (±0.14) |
| | | | | | | 604 | 39 (±0.24) |
| | | | | | | 802 | 38 (±0.20) |
| | | | | | | 1000 | 40 (±0.17) |
| PP-5.3 | 15¹⁾ | 50 | 15²⁾ | 50 | 1 | 10 | 12 (±1.71) |
| | | | | | | 50 | 41 (±0.30) |
| | | | | | | 104 | 41 (±0.50) |
| | | | | | | 203 | 40 (±0.26) |
| | | | | | | 401 | 43 (±0.36) |
| | | | | | | 604 | 42 (±0.42) |
| | | | | | | 802 | 42 (±0.42) |
| | | | | | | 1000 | 44 (±0.43) |
| PP-5.4 | 7.5¹⁾ | 25 | 22.5²⁾ | 75 | 0.33 | 10 | 15 (±5.91) |
| | | | | | | 50 | 37 (±1.42) |
| | | | | | | 104 | 39 (±1.11) |
| | | | | | | 203 | 36 (±0.54) |
| | | | | | | 401 | 39 (±0.69) |
| | | | | | | 604 | 38 (±0.70) |
| | | | | | | 802 | 38 (±0.82) |
| | | | | | | 1000 | 39 (±0.92) |
| PP-5.5 | 0 | — | 30²⁾ | 100 | — | 10 | 16 (±3.20) |
| | | | | | | 50 | 27 (±0.52) |
| | | | | | | 104 | 27 (±0.55) |
| | | | | | | 203 | 26 (±0.47) |
| | | | | | | 401 | 28 (±0.48) |
| | | | | | | 604 | 26 (±0.46) |
| | | | | | | 802 | 25 (±0.46) |
| | | | | | | 1000 | 25 (±0.45) |
| PP-5.6 | 15¹⁾ | 50 | 15³⁾ | 50 | 1 | 10 | 16 (±2.33) |
| | | | | | | 50 | 36 (±1.00) |
| | | | | | | 104 | 36 (±0.38) |
| | | | | | | 203 | 34 (±0.44) |
| | | | | | | 401 | 36 (±0.54) |
| | | | | | | 604 | 35 (±0.52) |
| | | | | | | 802 | 34 (±0.55) |
| | | | | | | 1000 | 35 (±0.60) |
| PP-5.7 | 15¹⁾ | 50 | 15⁴⁾ | 50 | 1 | 10 | 15 (±4.77) |
| | | | | | | 50 | 32 (±0.58) |
| | | | | | | 104 | 33 (±0.47) |
| | | | | | | 203 | 31 (±0.14) |
| | | | | | | 401 | 33 (±0.23) |
| | | | | | | 604 | 31 (±0.21) |
| | | | | | | 802 | 30 (±0.19) |
| | | | | | | 1000 | 31 (±0.17) |
| PP-5.8 | 7.5⁵⁾ | 33 | 15²⁾ | 67 | 1 | 10 | 16 (±1.44) |
| | | | | | | 50 | 32 (±0.24) |
| | | | | | | 104 | 32 (±0.08) |
| | | | | | | 203 | 31 (±0.09) |
| | | | | | | 401 | 33 (±0.19) |
| | | | | | | 604 | 31 (±0. 16) |
| | | | | | | 802 | 30 (±0.15) |
| | | | | | | 1000 | 31 (±0.15) |
| PP-5.9 | 15¹⁾ | 50 | 15⁶⁾ | 50 | — | 10 | 12 (±4.60) |
| | | | | | | 50 | 36 (±0.88) |
| | | | | | | 104 | 37 (±0.47) |
| | | | | | | 203 | 35 (±0.48) |
| | | | | | | 401 | 37 (±0.79) |
| | | | | | | 604 | 36 (±0.76) |
| | | | | | | 802 | 35 (±0.86) |
| | | | | | | 1000 | 36 (±0.95) |
| PP-5.10⁷⁾ | 10¹⁾ | 33 | 10²⁾ | 33 | 1 | 10 | 14 (±6.81) |
| | | | | | | 50 | 38 (±0.77) |
| | | | | | | 104 | 38 (±0.61) |
| | | | | | | 203 | 36 (±0.50) |
| | | | | | | 401 | 39 (±0.79) |
| | | | 10⁶⁾ | 33 | | 604 | 38 (±0.65) |
| | | | | | | 802 | 37 (±0.70) |
| | | | | | | 1000 | 38 (±0.76) |

*% of total filler content;
^{#}wt.-% ratio of carbon black (CB) to: i) expanded graphite (EG) or ii) EG + carbon fiber (CF) or iii) CF alone;
¹⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Expanded graphite = Timrex ® C-THERM ™ 301 from Imerys with D₉₀ = 30 μm;
⁴⁾Expanded graphite = Timrex ® C-THERM ™ MAX HD from Imerys with D₉₀ > 400 μm;
⁵⁾Carbon black = extra-conductive carbon black Ensaco ® 350G from Imerys with OAN of 320 mL/100 g and BET specific surface area under nitrogen of 770 m²/g; total loading of conductive additives only 22.5 wt.-% based on the total weight of the composition;
⁶⁾Carbon fiber Tenax A HT P802 3 mm from Teijin with fiber diameter of 7 μm and pellet length of 8 mm.
⁷⁾Conductive additives = 10 wt.-% CB (Ensaco ® 250G), 10 wt.-% EG (Timrex ® C-THERM ™ 011), 10 wt.-% carbon fiber (Tenax A HT P802) .

As can be derived from Table 5 and FIG. 5A and FIG. 5b, the corrected EMI shielding efficiencies of tested polypropylene composites decrease in the order: (i) sample PP-5.3 with 15 wt.-% carbon black (Ensaco® 250 G)/15 wt.-% expanded graphite (Timrex® C-THERM™ 011), (ii) sample PP-5.10 with 10 wt.-% carbon black (Ensaco® 250 G)/10 wt.-% expanded graphite (Timrex® C-THERM™ 011)/10 wt.-% carbon fiber (Tenax A HT P802 3 mm), (iii) sample PP-5.9 with 15 wt.-% carbon black (Ensaco® 250 G)/15 wt.-% carbon fiber (Tenax A HT P802 3 mm), (iv) sample PP-5.6 with 15 wt.-% carbon black (Ensaco® 250 G)/15 wt.-% expanded graphite (Timrex® C-THERM™ 301), (v) sample PP-5.7 with 15 wt. % carbon black (Ensaco® 250 G)/15 wt.-% expanded graphite (Timrex® C-THERM™ MAX HD), (vi) sample PP-5.8 with 7.5 wt.-% carbon black (Ensaco® 350 G)/15 wt.-% expanded graphite (Timrex® C-THERM™ 011), (vii) control sample with neat polypropylene without conductive additive.

Also, the sample PP-5.3 comprising 15 wt.-% carbon black (Ensaco® 250 G)/15 wt.-% expanded graphite (Timrex® C-THERM™ 011) shows an attenuation of about 40 to 45 dB in the frequency region of about 20 to about 1000 MHz. The present inventors surprisingly found that this composition is even superior to compositions with carbon fibers, emphasizing the extraordinary EMI shielding performance of compositions according to the present invention.

### Example 6: Measurement of the Thermal Conductivity

The inventors of the present invention found that blends of carbon black and expanded graphite according to the present invention advantageously provide for good thermal conductivity:

### 6.1 Thermal Conductivity Data for Polypropylene Compositions

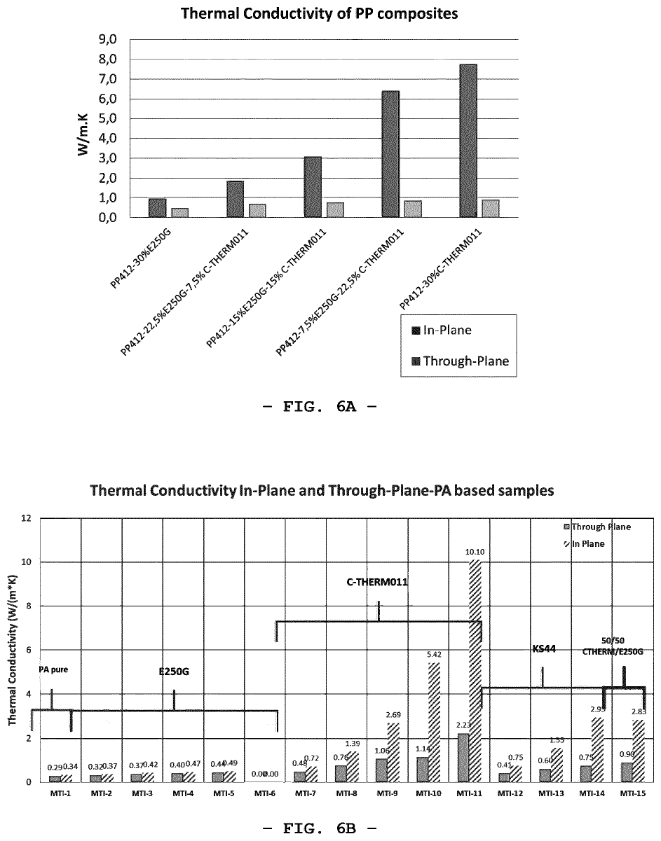

TABLE 6.1
Thermal conductivity data for polypropylene compositions
with blends of carbon black and expanded graphite
(samples PP-6.1 to PP-6.5) and compositions with blends of
different kinds of carbon black and different kinds of
expanded graphite (samples PP-6.6 to PP-6.8), optionally
with additional carbon fibers as conductive additives
(samples PP-6.9 to PP-6.10), also see FIG. 6A.

| | | | | | | Thermal | |
|---|---|---|---|---|---|---|---|
| | | | | | | conductivity/ | |
| | | | | | | W · m⁻¹K⁻¹ | |
| | CE/ | | EG/ | | Wt.-% | Through | In |
| Sample | wt.-% | %* | wt.-% | %* | ratio^{#} | plane | plane |
| Ctrl. | 0 | — | 0 | — | — | 0.23 | 0.31 |
| PP-6.1 | 30¹⁾ | 100 | 0 | — | — | 0.47 | 0.97 |
| PP-6.2 | 22.5¹⁾ | 75 | 7.5²⁾ | 25 | 3 | 0.70 | 1.86 |
| PP-6.3 | 15¹⁾ | 50 | 15²⁾ | 50 | 1 | 0.76 | 3.08 |
| PP-6.4 | 7.5¹⁾ | 25 | 22.5²⁾ | 75 | 0.33 | 0.87 | 6.40 |
| PP-6.5 | 0 | — | 30²⁾ | 100 | — | 0.90 | 7.75 |
| PP-6.6 | 15¹⁾ | 50 | 15 ³⁾ | 50 | 1 | 0.63 | 2.51 |
| PP-6.7 | 15¹⁾ | 50 | 15 ⁴⁾ | 50 | 1 | 0.68 | 1.91 |
| PP-6.8 | 7.5⁵⁾ | 33 | 15²⁾ | 67 | 1 | 0.67 | 2.62 |
| PP-6.9 | 15¹⁾ | 50 | 15 ⁶⁾ | 50 | — | 0.34 | 0.72 |
| PP-6.10⁷⁾ | 10¹⁾ | 33 | 10 ²⁾ | 33 | 1 | 0.55 | 1.97 |
| | | | 10 ⁶⁾ | 33 | | | |

*% of total filler content;
^{#}wt.-% ratio of carbon black (CB) to: i) expanded graphite (EG) or ii) EG + carbon fiber (CF) or iii) CF alone;
¹⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾ Expanded graphite = Timrex ® C-THERM ™ 301 from Imerys with D₉₀ = 30 μm;
⁴⁾ Expanded graphite = Timrex ® C-THERM ™ MAX HD from Imerys with D₉₀ > 400 μm;
⁵⁾Carbon black = extra-conductive carbon black Ensaco ® 350G from Imerys with OAN of 320 mL/100 g and BET specific surface area under nitrogen of 770 m²/g; total loading of conductive additives only 22.5 wt.-% based on the total weight of the composition;
⁶⁾ No expanded graphite but carbon fiber = Tenax A HT P802 3 mm from Teijin with fiber diameter of 7 μm and pellet length of 8 mm.
⁷⁾Conductive additives = 10 wt.-% CB (Ensaco ® 250G), 10 wt.-% EG (Timrex ® C-THERM ™ 011), 10 wt.-% carbon fiber (Tenax A HT P802).

As can be derived from Table 6.1 and FIG. 6A, for polypropylene compositions with blends of carbon black and expanded graphite, both through plane as well as in plane thermal conductivity increase with increasing amounts of expanded graphite (samples PP-6.1 to PP-6.5).

At equal additive loadings of 30 wt.-% and ratios of carbon black to expanded graphite of 1 (i.e. samples PP-6.3, PP-6.6 and PP-6.7), sample PP-6.3 with Timrex® C-THERM™ 011 from Imerys with D₉₀=90 μm as expanded graphite component provides for the highest thermal conductivity.

Also, use of carbon fibers results in inferior thermal conductivity compared with samples according to the present invention not comprising carbon fibers.

### 6.2. Thermal Conductivity Data for Polyamide Compositions

TABLE 6.2
Thermal conductivity data for polyamide compositions
with conductive fillers of single-component
additives and binary blends of carbon black and
expanded graphite, also see FIG. 6B.

| | | Total | Thermal conductivity/ | |
|---|---|---|---|---|
| | | amount | W · m⁻¹K⁻¹ | |
| | Filler | filler/ | Through | In |
| Sample | type | wt.-% | plane | plane |
| Ctrl. | — | 0 | 0.29 | 0.34 |
| PA-6.1 | CB¹⁾ | 5 | 0.32 | 0.37 |
| PA-6.2 | | 10 | 0.37 | 0.42 |
| PA-6.3 | | 15 | 0.40 | 0.47 |
| PA-6.4 | | 20 | 0.44 | 0.46 |
| PA-6.5 | EG²⁾ | 5 | 0.48 | 0.72 |
| PA-6.6 | | 10 | 0.76 | 1.39 |
| PA-6.7 | | 15 | 1.06 | 2.69 |
| PA-6.8 | | 20 | 1.14 | 5.42 |
| PA-6.9 | | 30 | 2.23 | 10.10 |
| PA-6.10 | SG³⁾ | 10 | 0.41 | 0.75 |
| PA-6.11 | | 20 | 0.60 | 1.55 |
| PA-6.12 | | 30 | 0.75 | 2.95 |
| PA-6.13 | Blend of | 25 | 0.90 | 2.83 |
| | CB¹⁾ + EG²⁾ | (12.5 CB + | | |
| | | 12.5 EG) | | |

¹⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Synthetic graphite = Timrex ® KS44 from Imerys with a BET specific surface area under nitrogen of ca. 9 m²/g and D₉₀ = 46 μm.

As can be derived from Table 6.2 and FIG. 6B, at equal filler loadings, both in-plane and through-plane thermal conductivity of polyamide samples with expanded graphite is higher than thermal conductivity of polyamide samples with synthetic graphite or carbon black.

Also, sample PA-6.13 with a blend of 12.5 wt.-% carbon black (Ensaco® 250G) and 12.5 wt.-% expanded graphite (Timrex® C-THERM™ 011) provides for similar in-plane thermal conductivity as sample PA-6.12 with 30 wt.-% synthetic graphite.

### Example 7: Measurement of Mechanical Properties: Tensile Strength

The inventors of the present invention found that blends of carbon black and expanded graphite according to the present invention advantageously provide for good tensile strength:

### 7.1. Tensile Strength Data for Polypropylene Compositions

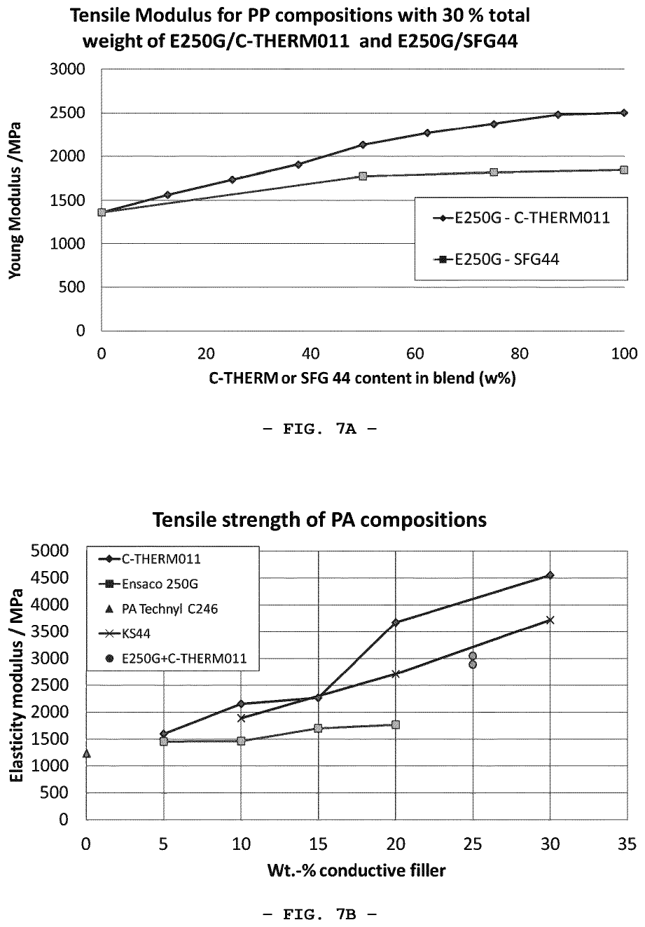

TABLE 7.1
Tensile strength data for polypropylene
compositions with blends of carbon black and
expanded graphite (samples PP-7.1 to PP-7.9)
or with synthetic graphite instead of expanded
graphite (samples PP-7.10 to PP-7.12), also
see FIG. 7A.

| | | | | | | Elasticity |
|---|---|---|---|---|---|---|
| | CB¹⁾/ | | EG^{2)/} | | CB¹⁾: | modulus/ |
| Sample | wt.-% | %* | wt.-% | %* | EG^{2)#} | MPa |
| PP-7.1 | 30 | 100 | 0 | — | — | 1362 (±51) |
| PP-7.2 | 26.2 | 87.3 | 3.8 | 12.7 | 6.9 | 1562 (±34) |
| PP-7.3 | 22.5 | 75 | 7.5 | 25 | 3 | 1734 (±42) |
| PP-7.4 | 18.7 | 62 | 11.3 | 38 | 1.65 | 1907 (±41) |
| PP-7.5 | 15 | 50 | 15 | 50 | 1 | 2130 (±16) |
| PP-7.6 | 11.3 | 38 | 18.7 | 62 | 0.6 | 2269 (±22) |
| PP-7.7 | 7.5 | 25 | 22.5 | 75 | 0.33 | 2373 (±21) |
| PP-7.8 | 3.8 | 12.7 | 26.2 | 87.3 | 0.15 | 2477 (±33) |
| PP-7.9 | 0 | — | 30 | 100 | — | 2500 (±58) |
| | | | | | | Elasticity |
| | CB¹⁾/ | | SG³⁾/ | | CB¹⁾: | modulus/ |
| Sample | wt.-% | %* | wt.-% | %* | SG^{3)#} | MPa |
| PP-7.10 | 15 | 50 | 15 | 50 | 1 | 1774 (±51) |
| PP-7.11 | 7.5 | 25 | 22.5 | 75 | 0.33 | 1820 (±25) |
| PP-7.12 | 0 | — | 30 | 100 | — | 1846 (±65) |

*% of total filler content;
^{#}wt.-% ratio of carbon black (CB) and expanded graphite (EG) or synthetic graphite (SG);
¹⁾Carbon black = Ensaco ® 250G″ from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾Synthetic graphite = Synthetic graphite = Timrex ® SFG44 Primary Synthetic Graphite from Imerys with BET specific surface area of ca. 5 m²/g and D₉₀ = 50 μm.

The inventors of the present invention surprisingly found that compositions according to the invention of carbon black and expanded graphite provide for superior tensile properties when compared to blends of carbon black and synthetic graphite: As can be derived from Table 7.1 and FIG. 7A, an increasing amount of expanded graphite in polypropylene compositions provides for greater elasticity moduli (Young moduli). This effect is also observed for compositions with synthetic graphite, although to a lesser extent. Also, at equal filler amounts of 30 wt.-% and equal ratios of carbon black to expanded graphite and synthetic graphite, respectively, blends of carbon black and expanded graphite advantageously provide for greater elasticity moduli (Young moduli).

### 7.2. Tensile Strength Data for Polyamide Compositions

TABLE 7.2
Tensile strength data for polyamide compositions
with conductive fillers of single-component
additives and binary blends of carbon black and
expanded graphite, also see FIG. 7B.

| | | Total amount | Elasticity | |
|---|---|---|---|---|
| | | filler/ | modulus/ | St. dev./ |
| Sample | Filler type | wt.-% | MPa | MPa |
| Ctrl. | — | 0 | 1233.54 | 313.10 |
| PA-7.1 | CB¹⁾ | 5 | 1451.97 | 209.70 |
| PA-7.2 | | 10 | 1467.48 | 202.20 |
| PA-7.3 | | 15 | 1699.73 | 196.20 |
| PA-7.4 | | 20 | 1768.78 | 75.80 |
| PA-7.5 | EG²⁾ | 5 | 1594.32 | 91.20 |
| PA-7.6 | | 10 | 2150.04 | 74.00 |
| PA-7.7 | | 15 | 2268.10 | 93.80 |
| PA-7.8 | | 20 | 3670.68 | 144.50 |
| PA-7.9 | | 30 | 4545.61 | 182.80 |
| PA-7.10 | SG ³⁾ | 10 | 1887.52 | 117.90 |
| PA-7.11 | | 20 | 2709.60 | 143.70 |
| PA-7.12 | | 30 | 3718.11 | 109.40 |
| PA-7.13 | Blend of | 25 | 3044.65 | 107.20 |
| | CB¹⁾ + EG²⁾ | (12.5 CB + | 2892.05 | 112.00 |
| | | 12.5 EG) | | |

¹⁾Carbon black = Ensaco ® 250G from Imerys with OAN = 190 mL/g and BET specific surface area under nitrogen of 65 m²/g;
²⁾Expanded graphite = Timrex ® C-THERM ™ 011 from Imerys with D₉₀ = 90 μm;
³⁾ Synthetic graphite = Timrex ® KS44 from Imerys with a BET specific surface area under nitrogen of ca. 9 m²/g and D₉₀ = 46 μm.

### CITED DOCUMENTS

WO 2012/020099 A1
U.S. Pat. No. 1,137,373
U.S. Pat. No. 1,191,383
U.S. Pat. No. 4,946,982
U.S. Pat. No. 5,582,781
U.S. Pat. No. 4,530,949
U.S. Pat. No. 4,704,231
US 2006/0148965 A1
US 2018/0022398 A
U.S. Pat. No. 11,024,849 B2
Leão et al., Journal of Polymers and the Environment, 2020, 28, pp. 2021-2100, https://doi.org/10.1007/s10924-020-01753-4

### LIST OF EMBODIMENTS

A 1st embodiment of the present invention relates to a composition comprising
(a) carbon black in an amount of 3 to 40, or 5 to 35, or 10 to 30, or 12 to 26, or 13 to 18 wt.-% based on the total weight of the composition;
   and
(b) expanded graphite in an amount of 3 to 50, or 3 to 40, or 3 to 35, or 3 to 30, or 3.5 to 20, or 4 to 18, or 5 to 17, or 7 to 15 wt.-% based on the total weight of the composition.

A 2nd embodiment of the present invention relates to a composition according to the 1st embodiment, wherein the combined amounts of carbon black and expanded graphite are 10 to 50, or 17 to 45, or 19 to 40, or 20 to 35, or 22 to 34, or 24 to 31, or 25 to 30 wt.-% based on the total weight of the composition.

A 3^{rd} embodiment of the present invention relates to a composition according to any one of the preceding embodiments, wherein the ratio of wt.-% based on the total weight of the composition of carbon black to expanded graphite is in the range of 0.1 to 9, or 0.33 to 9, or 0.4 to 9, or 0.4 to 7, or 0.4 to 5, or 0.4 to 3, or 0.4 to 2, or 0.6 to 1.7.

A 4^{th} embodiment of the present invention relates to a composition according to any one of the preceding embodiments, wherein the carbon black is characterized by
a BET specific surface area measured according to ASTM D-3037 under nitrogen of less than 950 m²·g⁻¹, or less than 850 m²·g⁻¹, or less than 700 m²·g⁻¹, or less than 600 m²·g⁻¹, or less than 500 m²·g⁻¹, in particular in the range of 40 to 800, or 50 to 800, or 30 to 100, or 50 to 80, or 60 to 70 m²·g⁻¹
and, optionally, one or more of the following:
a primary particle size measured according to ASTM D-3849-14a of 10 to 60, preferably 15 to 55, more preferably 20 to 40, even more preferably 25 to 35 nm; and/or
an oil absorption number OAN when measured according to ASTM D-2414-01 of less than 400 ml·g⁻¹, or less than 390 ml·g⁻¹, or less than 380 ml·g⁻¹, or less than 370 ml·g⁻¹, or less than 350 ml·g⁻¹, in particular in the range of 100 to 330, or 150 to 230, or 170 to 210, or 180 to 200, or 185 to 195 ml·g⁻¹.

A 5th embodiment of the present invention relates to a composition according to any one of the preceding embodiments, wherein the expanded graphite is characterized by one or more of the following:
a particle size distribution D₉₀ when measured according to ISO 13220 of 5 to 1000, or 20 to 800, or 30 to 700, or 50 to 600, or 70 to 500, or 80 to 250, or 85 to 150 μm;
and/or
a bulk density when measured according to ASTM D-7481 of 0.01 to 1.00, or 0.02 to 0.9, or 0.05 to 0.7, even or 0.1 to 0.55, or 0.13 to 0.50, or 0.16 to 0.45, or 0.16 to 0.25 g·cm⁻³.

A 6th embodiment of the present invention relates to a composition comprising
(a) carbon black; and
(b) expanded graphite;
wherein the carbon black is characterized
   by a BET specific surface area measured according to ASTM D-3037 under nitrogen of less than 950 m²·g⁻¹, or less than 850 m²·g⁻¹, or less than 700 m²·g⁻¹, or less than 600 m²·g⁻¹, or less than 500 m²·g⁻¹, in particular in the range of 40 to 800, or 50 to 800, or 30 to 100, or 50 to 80, or 60 to 70 m²·g⁻¹;
and, optionally, one or more of the following:
   a primary particle size measured according to ASTM D-3849-14a of 10 to 60, or 15 to 55, or 20 to 40, or 25 to 35 nm; and/or
   an oil absorption number OAN when measured according to ASTM D-2414 of less than 400 ml·g⁻¹, or less than 390 ml·g⁻¹, or less than 380 ml·g⁻¹, or less than 370 ml·g⁻¹, or less than 350 ml·g⁻¹, in particular in the range of 100 to 330, or 150 to 230, or 170 to 210, or 180 to 200, or 185 to 195 ml·g⁻¹;
and/or
wherein the expanded graphite is characterized by one or more of the following:
   a particle size distribution D₉₀ when measured according to ISO 13220 of 5 to 1000, or 20 to 800, or 30 to 700, or 50 to 600, or 70 to 500, or 80 to 250, or 85 to 150 μm;
   and/or
   or a bulk density when measured according to ASTM D-7481 of 0.01 to 1.00, or 0.02 to 0.9, or 0.05 to 0.7, or 0.1 to 0.55, or 0.13 to 0.50, or 0.16 to 0.45, or 0.16 to 0.25 g·cm⁻³.

A 7th embodiment of the present invention relates to a composition according to the 6th embodiment, wherein the composition comprises the carbon black in an amount of 3 to 40, or 5 to 35, or 10 to 30, or 12 to 26, or 13 to 18 wt.-% based on the total weight of the composition.

An 8th embodiment of the present invention relates to a composition according to any one of the 6th or 7th embodiments, wherein the composition comprises expanded graphite in an amount of 3 to 50, or 3 to 40, or 3 to 35, or 3 to 30, or 3.5 to 20, or 4 to 18, or 5 to 17, or 7 to 15 wt.-% based on the total weight of the composition.

A 9th embodiment of the present invention relates to a composition according to any one of the 6th to the 8th embodiment, wherein the composition comprises carbon black and expanded graphite in a combined amount of 10 to 50, or 17 to 45, or 19 to 40, or 20 to 35, or 22 to 34, or 24 to 31, or 25 to 30 wt.-% based on the total weight of the composition.

A 10th embodiment of the present invention relates to a composition according to any one of the 6th to the 9th embodiment, wherein the ratio of wt.-% based on the total weight of the composition of carbon black to graphite is in the range of 0.1 to 9, or 0.33 to 9, or 0.4 to 9, or 0.4 to 7, or 0.4 to 5, or 0.4 to 3, or 0.4 to 2, or 0.6 to 1.7.

An 11th embodiment of the present invention relates to a composition comprising carbon black and expanded graphite, wherein the ratio of wt.-% based on the total weight of the composition of carbon black to graphite is in the range of 0.1 to 9, or 0.33 to 9, or 0.4 to 9, or 0.4 to 7, or 0.4 to 5, or 0.4 to 3, or 0.4 to 2, or 0.6 to 1.7 and
wherein the carbon black is characterized by a BET specific surface area measured according to ASTM D-3037 under nitrogen of less than 950 m²·g⁻¹, or less than 850 m²·g⁻¹, or less than 700 m²·g⁻¹, or less than 600 m²·g⁻¹, or less than 500 m²·g⁻¹, in particular in the range of 40 to 800, or 50 to 800, or 30 to 100, or 50 to 80, or 60 to 70 m²·g⁻¹;
and, optionally, one or more of the following:
   a primary particle size measured according to ASTM D-3849-14a of 10 to 60, or 15 to 55, or 20 to 40, or 25 to 35 nm; and/or
   an oil absorption number OAN when measured according to ASTM D-2414 of less than 400 ml·g⁻¹, or less than 390 ml·g⁻¹, or less than 380 ml·g⁻¹, or less than 370 ml·g⁻¹, or less than 350 ml·g⁻¹, in particular in the range of 100 to 330, or 150 to 230, or 170 to 210, or 180 to 200, or 185 to 195 ml·g⁻¹;
and/or
wherein the expanded graphite is characterized by one or more of the following:
   a particle size distribution D₉₀ when measured according to ISO 13220 of 5 to 1000, or 20 to 800, or 30 to 700, or 50 to 600, or 70 to 500, or 80 to 250, or 85 to 150 μm;
   and/or
   or a bulk density when measured according to ASTM D-3037 of 0.01 to 1.00, or 0.02 to 0.9, or 0.05 to 0.7, or 0.1 to 0.55, or 0.13 to 0.50, or 0.16 to 0.45, or 0.16 to 0.25 g·cm⁻³.

A 12th embodiment of the present invention relates to a composition according to the 11th embodiment, wherein the composition comprises the carbon black in an amount of 3 to 40, or 5 to 35, or 10 to 30, or 12 to 26, or 13 to 18 wt.-% based on the total weight of the composition.

A 13th embodiment of the present invention relates to a composition according to any one the 11th or 12th embodiments, wherein the composition comprises the expanded graphite in an amount of 3 to 50, or 3 to 40, or 3 to 35, or 3 to 30, or 3.5 to 20, or 4 to 18, or 5 to 17, or 7 to 15 wt.-% based on the total weight of the composition.

A 14th embodiment of the invention relates to a composition according to any one of the 11th to the 13th embodiment, wherein the composition comprises carbon black and expanded graphite in a combined amount of 10 to 50, or 17 to 45, or 19 to 40, or 20 to 35, or 22 to 34, or 25 to 30 wt.-% based on the total weight of the composition.

A 15th embodiment of the present invention relates to a composition according to any one of the preceding embodiments comprising one or more further fillers selected from the group consisting of metal powder, metal flakes, glass fibers, silicon fibers, carbon-based fillers selected from the group consisting of carbon conductive additives, natural graphite, synthetic graphite, surface modified graphite, graphite nanoplatelets, multiwall carbon nanotubes, single wall carbon nanotube, carbon nanostructures, metal-coated graphite, and combinations thereof.

A 16th embodiment of the present invention relates to a composition according to any one of the preceding embodiments comprising a polymer, preferably, the polymer being selected from the from the group consisting of polyolefins, preferably the polyolefins being selected from polyethylene, propylene and combinations thereof, more preferably the polyolefins are polypropylene, polyamides, polymethylmethacrylate (PMMA), polyacetal, polycarbonate, polyvinyls, polyacrylonitrile, polybutadiene, polystyrene, polyacrylate, epoxy polymers, polyesters, polycarbonates, polyketones, polysulfones, unsaturated polyesters, polyurethanes, polycyclopentadienes, silicones, rubber, thermosets, thermoplastics, binders for coating and combinations thereof.

A 17th embodiment of the present invention relates to a shaped article of composite material comprising the composition according to any one of the 1st to the 16th embodiment.

An 18th embodiment of the present invention relates to a substrate coated with a coating comprising the composition according to any one of the 1st to the 16th embodiment.

A 19th embodiment of the present invention relates to the shaped article according to the 17th embodiment or the coated substrate according to the 18th embodiment comprising a polymer selected from the group consisting of polyolefins, preferably the polyolefins being selected from polyethylene, polypropylene and combinations thereof, more preferably the polyolefins are polypropylene, polyamides, polymethylmethacrylate (PMMA), polyacetal, polycarbonate, polyvinyls, polyacrylonitrile, polybutadiene, polystyrene, polyacrylate, epoxy polymers, polyesters, polycarbonates, polyketones, polysulfones, unsaturated polyesters, polyurethanes, polycyclopentadienes, silicones, rubber, thermosets, thermoplastics, binders for coating and combinations thereof.

A 20th embodiment of the present invention relates to the shaped article or the coated substrate according to the 19th embodiment, wherein the carbon black and the expanded graphite are dispersed in the polymer.

A 21st embodiment of the present invention relates to the use of the composition according to any one of the 1st to the 16th embodiment or the shaped article according to the 17th or 19th to 20th embodiments or the coated substrate according to any one of the 18th to the 20th embodiments for providing one or more of the following:
electro-magnetic interference (EMI) shielding measured according to ASTM D-4935 at a frequency of 10 to 1000 MHz or method derived therefrom as detailed in the paper E. Hariya and U. Massahiro, “Instruments for Measuring Shielding Effectiveness”, EMC 1984 Tokyo, wherein the EMI shielding is at least 20 dB, or at least 30 dB, or at least 40 dB;
volume resistivity measured according to ASTM D-4496, wherein the volume resistivity is less than 1000 Ohm·cm, or less than 100 Ohm·cm, or less than 10 Ohm·cm, or less than 1 Ohm·cm; and/or
in-plane thermal conductivity measured according to ASTM E 1461 wherein the in-plane thermal conductivity is greater than 0.5 Wm⁻¹K⁻¹, or greater than 0.7 Wm⁻¹K⁻¹, or greater than 0.9 Wm⁻¹K⁻¹, or greater than 1.1 Wm⁻¹K⁻¹, or greater than 1.3 Wm⁻¹K⁻¹, or greater than 1.5 Wm⁻¹K⁻¹, or greater than 1.7 Wm⁻¹K⁻¹, or greater than 2.0 Wm⁻¹K⁻¹, or greater than 2.5 Wm⁻¹K⁻¹, or greater than 3.0 Wm⁻¹K⁻¹, or greater than 4.0 Wm⁻¹K⁻¹, or greater than 5.0 Wm⁻¹K⁻¹, or greater than 6.0 Wm⁻¹K⁻¹, or greater than 7.0 Wm⁻¹K⁻¹.

A 22nd embodiment of the present invention relates to a method of providing electromagnetic interference (EMI) shielding measured according to ASTM D-4935 at a frequency of 10 MHz to 1000 MHz or method derived therefrom as detailed in the paper E. Hariya and U. Massahiro, “Instruments for Measuring Shielding Effectiveness”, EMC 1984 Tokyo in a polymeric composition using the composition according to any one of the 1st to the 16th embodiment or the shaped article according to the 17th or 19th to 20th embodiments or the coated substrate according to any one of the 18th to the 20th embodiments, wherein the EMI shielding is at least 20 dB, or at least 30 dB, or at least 40 dB.

A 23rd embodiment of the present invention relates to a method of providing volume resistivity when measured according to standard test method ASTM D-4496 in a polymeric composition using the composition according to any one of the 1st to the 16th embodiment or the shaped article according to the 17th or 19th to 20th embodiments or the coated substrate according to any one of the 18th to the 20th embodiments wherein the volume resistivity is less than 1000 Ohm·cm, or less than 100 Ohm·cm, or less than 10 Ohm·cm, or less than 1 Ohm·cm.

A 24th embodiment of the present invention relates to a method of providing in-plane thermal conductivity measured according to ASTM E 1461 in a polymeric composition using the composition according to any one of the 1st to the 16th embodiments or the shaped article according to the 17th or 19th to 20th embodiments or the coated substrate according to any one of the 18th to the 20th embodiments, wherein the in-plane thermal conductivity is greater than 0.5 Wm⁻¹K⁻¹, or greater than 0.7 Wm⁻¹K⁻¹, or greater than 0.9 Wm⁻¹K⁻¹, or greater than 1.1 Wm⁻¹K⁻¹, or greater than 1.3 Wm⁻¹K⁻¹, or greater than 1.5 Wm⁻¹K⁻¹, or greater than 1.7 Wm⁻¹K⁻¹, or greater than 2.0 Wm⁻¹K⁻¹, or greater than 2.5 Wm⁻¹K⁻¹, or greater than 3.0 Wm⁻¹K⁻¹, or greater than 4.0 Wm⁻¹K⁻¹, or greater than 5.0 Wm⁻¹K⁻¹, or greater than 6.0 Wm⁻¹K⁻¹, or greater than 7.0 Wm⁻¹K⁻¹.

A 25th embodiment of the present invention relates to the use or the method of providing electromagnetic interference (EMI) shielding according to of any one of the 21st or 22nd embodiments, wherein the EMI shielding is improved by at least 10 dB, or at least 20 dB, or at least 25 dB, or at least 30 dB, or at least 35 dB, or at least 40 dB, or at least 45 dB, in particular by 10 to 80 dB, or 15 to 70 dB, or 18 to 60 dB, or 20 to 55 dB, or 25 to 50 dB, or 27 to 50 dB, or 30 to 50 dB, or 31 to 45 dB, or 35 to 42 dB when compared to a reference material not comprising carbon black, expanded graphite or any other conductive filler or additive, in particular a composition according to any one of the 1st to the 16th embodiments.

A 26th embodiment of the present invention relates to the use or the method of providing volume resistivity according to any one of the 21st or 23rd embodiments, wherein the volume resistivity is reduced by a factor of 1.3 to 109, or 1.5 to 108, or 2 to 107, or 2 to 106, or 2 to 105, or 3 to 105, or 3 to 104, or 5 to 104, or 7 to 104, or 7 to 103, or 10 to 103, or 15 to 103, or 50 to 103, or 102 to 103 when compared to a reference material not comprising carbon black, expanded graphite or any other conductive filler or additive, in particular a composition according to any one of the 1st to the 16th embodiments.

A 27th embodiment of the present invention relates to the use or the method of providing in-plane thermal conductivity according to any one of the 21st or 24th embodiments, wherein the in-plane thermal conductivity is increased by a factor of 2, or 3, or 4, or 5, or 6, or 7, or 8, or 9, or 10, or 12, or 14, or 16, or 18, or 20, or 25, or 30, or 40, or 50 when compared to a reference material not comprising carbon black, expanded graphite or any other conductive filler or additive, in particular a composition according to any one of the 1st to the 16th embodiments.

1-5. (canceled)

6. Composition comprising
(a) carbon black; and
(b) expanded graphite;
wherein the carbon black is characterized
by a BET specific surface area measured according to ASTM D-3037 under nitrogen of less than 950 m²·g⁻¹;
wherein the expanded graphite is characterized by one or more of the following:
a particle size distribution D₉₀ when measured according to ISO 13220 of 5 to 1000 μm;
and/or
a bulk density when measured according to ASTM D-7481 standard of 0.01 to 1.00 g·cm⁻³.

7. The composition of claim 6, wherein the composition comprises the carbon black in an amount of 3 to 40 wt.-% based on the total weight of the composition; and
wherein the composition comprises expanded graphite in an amount of 3 to 50 wt. %.

8. (canceled)

9. The composition according to claim 7, wherein the composition comprises carbon black and expanded graphite in a combined amount of 10 to 50 wt.-% based on the total weight of the composition.

10. The composition according to claim 9, wherein the ratio of wt.-% based on the total weight of the composition of carbon black to graphite is in the range of 0.1 to 9.

11. Composition comprising carbon black and expanded graphite, wherein the ratio of wt.-% based on the total weight of the composition of carbon black to graphite is in the range of 0.1 to 9
and
wherein the carbon black is characterized by a BET specific surface area measured according to ASTM D-3037 under nitrogen of less than 950 m²·g⁻¹;
and/or
wherein the expanded graphite is characterized by one or more of the following:
a particle size distribution Do when measured according to ISO 13220 of 5 to 1000 μm;
and/or
a bulk density when measured according to ASTM D-3037 of 0.01 to 1.00 g·cm⁻³.

12. The composition of claim 11, wherein the composition comprises the carbon black in an amount of 3 to 40 wt.-% based on the total weight of the composition; and
wherein the composition comprises the expanded graphite in an amount of 3 to 50 wt.-% based on the total weight of the composition.

13. The composition according to claim 11, wherein the carbon black s characterized by one or more of the following:
a primary article size measured according to ASTM D-3849-14a of 10 to 60 nm; and/or
an oil absorption number OAN when measured according to ASTM D-2414 of less than 400 ml·g⁻¹.

14. The composition according to claim 11, wherein the composition comprises carbon black and expanded graphite in a combined amount of 10 to 50 wt.-% based on the total weight of the composition.

15. The composition according to claim 6 comprising one or more fillers selected from the group consisting of metal powder, metal flakes, glass fibers, silicon fibers, carbon-based fillers selected from the group consisting of carbon conductive additives, natural graphite, synthetic graphite, surface modified graphite, graphite nanoplatelets, multiwall carbon nanotubes, single wall carbon nanotube, carbon nanostructures, metal-coated graphite, and combinations thereof.

16. The composition according to claim 6 comprising a polymer.

17. A shaped article of composite material comprising the composition according to claim 16.

18-19. (canceled)

20. The shaped article of claim 17, wherein the carbon black and the expanded graphite are dispersed in the polymer.

21. (canceled)

22. Method of providing electromagnetic interference (EMI) shielding measured according to ASTM D-4935 at a frequency of 10 MHz to 1000 MHz in a polymeric composition using the composition of claim 6, wherein the EMI shielding is at least 20 dB.

23. Method of providing volume resistivity when measured according to standard test method ASTM D-4496 in a polymeric composition using the composition of claim 6, wherein the volume resistivity is less than 1000 Ohm·cm.

24. Method of providing in-plane thermal conductivity measured according to ASTM E 1461 in a polymeric composition using the composition of claim 6, wherein the thermal conductivity is greater than 0.5 W·m⁻¹K⁻¹.

25. The method of providing electromagnetic interference (EMI) shielding of claim 22, wherein the EMI shielding is improved by at least 10 dB when compared to a reference material not comprising a composition according to claim 6.

26. The method of providing volume resistivity of claim 23, wherein the volume resistivity is reduced by a factor of 1.3 to 10⁹ when compared to a reference material not comprising a composition according to claim 6.

27. The method of providing thermal conductivity of claim 24, wherein the thermal conductivity is increased by a factor of 2 when compared to a reference material not comprising composition according to claim 6&.

28. The composition according to claim 6, wherein the carbon black is characterized by a BET specific surface area measured according to ASTM D-3037 under nitrogen of less than 850 m²·g⁻¹.

29. The composition according to claim 6, wherein the expanded graphite is characterized by one or more of the following:
a particle size distribution D₉₀ when measured according to ISO 13220 of 20 to 800 μm;
and/or
a bulk density when measured according to ASTM D-7481 standard of 0.02 to 0.9 g·cm⁻³.
